(19) United States
(12) Patent Application Publication
(10) Pub. No.: US 2008/0239797 A1
(43) Pub. Date: Oct. 2, 2008

(54) INFORMATION RECORDING/REPRODUCING DEVICE

(75) Inventors: Takayuki Tsukamoto, Kawasaki-shi (JP); Kohichi Kubo, Yokohama-shi (JP); Chikayoshi Kamata, Kawasaki-shi (JP); Takahiro Hirai, Yokohama-shi (JP); Shinya Aoki, Yokohama-shi (JP); Toshiro Hiraoka, Yokohama-shi (JP)

Correspondence Address: CHARLES N.J. RUGGIERO;OHLANDT, GREELEY, RUGGIERO & PERLE, L.L.P., 10th FLOOR, ONE LANDMARK SQUARE, STAMFORD, CT, 06901-2682, US

(73) Assignee: KABUSHIKI KAISHA TOSHIBA

(21) Appl. No.: 11/954,370

(22) Filed: Dec. 12, 2007

Related U.S. Application Data
(63) Continuation of application No. PCT/JP2007/061828, filed on Jun. 12, 2007.

(30) Foreign Application Priority Data
Mar. 30, 2007 (JP) 2007-094628

(51) Int. Cl. G11C 11/00

(52) U.S. Cl. 365/163; 365/148

(57) ABSTRACT

There is proposed a nonvolatile information recording/reproducing device with low power consumption and high thermal stability. The information recording/reproducing device according to an aspect of the present invention includes a recording layer, and mechanism for recording information by generating a phase change in the recording layer while applying a voltage to the recording layer. The recording layer is comprised one of a Wolframite structure and a Scheelite structure.

### CROSS REFERENCE TO RELATED APPLICATIONS

This is a Continuation Application of PCT Application No. PCT/JP2007/061828, filed Jun. 12, 2007, which was published under PCT Article 21(2) in Japanese.

This application is based upon and claims the benefit of priority from prior Japanese Patent Application No. 2007-094628, filed Mar. 30, 2007, the entire contents of which are incorporated herein by reference.

### BACKGROUND OF THE INVENTION

1. Field of the Invention

The present invention relates to an information recording/reproducing device with a high recording density.

2. Description of the Related Art

In recent years, compact portable devices have been widely used worldwide and, at the same time, a demand for a small-sized and large-capacity nonvolatile memory has been expanding rapidly along with the extensive progress of a high-speed information transmission network. Among them, particularly a NAND type flash memory and a small-sized HDD (hard disk drive) have rapidly evolved in recording density, and accordingly, they now form a large market.

In the same vain, some ideas for a new memory, which aim at greatly surpassing the present recording density limit, is proposed.

For instance, investigated are a ternary oxide including a transition metal element such as Perovskite (for instance, refer to JP-A 2005-317787 (KOKAI), and JP-A 2006-80259 (KOKAI)), and a binary oxide of a transition metal (for instance, refer to JP-A 2006-140464 (KOKAI)). When using these materials, it is possible to change states repeatedly between a high resistance state (OFF) and a low resistance state (ON) by applying the voltage pulse, and thus there is adopted a principle of recording data upon homologizing these two states to binary data “0”, “1”, respectively.

Concerning write/erase, for example, a method of applying pulses of opposed polarity is used in the ternary oxide. That is, when changing phase from a low resistance state phase to a high resistance state phase, the pulse of one polarity is used, while when changing phase from a high resistance state phase to a low resistance state phase, the pulse of an opposed polarity is used. Similarly, in the binary oxide, in some cases, there is also performed write/erase by applying pulses with different pulse amplitude or different pulse width.

A read is performed by measuring the electric resistance of a recording material while causing a small degree of read current to flow, by which a write/erase is not generated in the recording material. Generally, the ratio of resistance between the resistance of the high resistance state phase and the resistance of the low resistance state phase is about 10³.

The greatest feature of these materials is that, even though the element is reduced to about 10 nm, the element can be operated in principle, and in this case, the material can realize a recording density of about 10 Tbpsi (tera bite par square inch). Therefore, this is one of the promising materials for realizing a high recording density.

As an operation mechanism of such a new memory, there are following proposals. Concerning the Perovskite material, there are proposed the diffusion of an oxygen defect, the charge storage for an interface state, and the like. Similarly, as for the binary oxide, there are proposed the diffusion of oxygen ions, Mott transition, and the like. Although the details of the mechanism are not that clear, there are observed similar resistance changes in various material systems. Therefore, the mechanism is noticed as one candidate for increased recording density.

In addition to the above, there is proposed an MEMS memory using the MEMS (micro electro mechanical systems) technique. The greatest feature of such MEMS memory lies in a point that since it is not necessary to provide wiring in each recording part for recording bit data, the recording density can be improved remarkably. Various recording media and recording principles have been proposed in order to achieve a large improvement, concerning power consumption, recording density and working speed while combining the MEMS technique with a new recording principle.

However, a new information recording medium using such new recording materials has not been realized, because the power consumption is too large and the thermal stability in each resistance state is too low (for instance, refer to S. Seo et al. “Applied Physics Letters, vol. 85, p.p. 5655 to 5657, (2004)”).

### BRIEF SUMMARY OF THE INVENTION

The present invention proposes a nonvolatile information recording/reproducing device with low power consumption and high thermal stability.

The inventors of the present invention have found, as a result of conducting earnest investigation, that the diffusion of cations in an oxide and accompanying valence change of the cations contributes to the resistance change phenomenon in the oxide.

In accordance with the finding, in order to generate the resistance change with small power consumption, it is necessary to make the cations easily diffusable. Meanwhile, in order to improve the thermal stability of each resistance state, it is important to stably maintain the host structure after the cations are diffused.

In the present invention based on such a finding, the recording layer consists of a material which has a diffusion path for diffusable cations to generate a resistance change with a small power consumption, and has undiffusable cations of a large valence in order to maintain the host structure after the cations are diffused.

Therefore, an information recording/reproducing device according to the present invention comprises: a recording layer; and means for recording information by generating a phase change in the recording layer while applying a voltage to the recording layer, wherein the recording layer is configured to include a first chemical compound having at least a “Wolframite structure and/or similar one” or “Scheelite structure and/or similar one”.

According to an example of the present invention, it is possible to realize a nonvolatile information recording/reproducing device with a low power consumption and a high thermal stability, by making cations easily diffusable and maintaining a host structure stably, while using a recording layer having a “Wolframite structure and/or similar one” or “Scheelite structure and/or similar one”.

### BRIEF DESCRIPTION OF THE SEVERAL VIEWS OF THE DRAWING

FIG. 1 is a view showing a recording principle.

FIG. 2 is a view showing a recording principle.

FIG. 3 is a view showing a recording principle.

FIG. 4 is a view showing a probe memory according to an example.

FIG. 5 is a view showing a recording medium.

FIG. 6 is a view showing a state at the time of recording of a probe memory.

FIG. 7 is a view showing a write operation.

FIG. 8 is a view showing a read operation.

FIG. 9 is a view showing a write operation.

FIG. 10 is a view showing a read operation.

FIG. 11 is a view showing a semiconductor memory according to an example.

FIG. 12 is a view showing an example of a memory cell array structure.

FIG. 13 is a view showing an example of a memory cell structure.

FIG. 14 is a view showing an example of a memory cell array structure.

FIG. 15 is a view showing an example of a memory cell array structure.

FIG. 16 is a view showing an application example for a flash memory.

FIG. 17 is a circuit diagram showing a NAND cell unit.

FIG. 18 is a view showing a structure of a NAND cell unit.

FIG. 19 is a view showing a structure of a NAND cell unit.

FIG. 20 is a view showing a structure of a NAND cell unit.

FIG. 21 is a circuit diagram showing a NOR cell.

FIG. 22 is a view showing a structure of a NOR cell.

FIG. 23 is a circuit diagram showing a 2-transistor cell unit.

FIG. 24 is a view showing a structure of a 2-transistor cell unit.

FIG. 25 is a view showing a structure of a 2-transistor cell unit.

FIG. 26 is a view for explaining a recording principle.

FIG. 27 is a view for explaining a recording principle.

FIG. 28 is a view showing an example of a memory cell array structure.

FIG. 29 is a view showing an example of a memory cell array structure.

FIG. 30 is a view showing a modified example of a recording layer.

FIG. 31 is a view showing a modified example of a recording layer.

### DETAILED DESCRIPTION OF THE INVENTION

### 1. Outline

(1) An information recording/reproducing device according to a first example of the present invention has a stacked-structure-shaped recording section including an electrode layer, a recording layer, and an electrode layer (or protection layer).

It is possible to reduce the power consumption necessary for the resistance change and to increase the thermal stability by using a material having a “Wolframite structure and/or similar one” or “Scheelite structure and/or similar one” for the recording layer.

(2) An information recording/reproducing device according to a second example of the present invention is comprised by a first chemical compound in which the recording layer has the “Wolframite structure and/or similar one” or the “Scheelite structure and/or similar one”, and a second chemical compound having a vacant site capable of accommodating cations.

The second chemical compound is comprised by one of chemical formula 2 to chemical formula 6:

□_{X}MZ₂ Chemical formula 2:

where □ is the vacant site in which the above-described X ion is accommodated, M is at least one element selected from Ti, V, Cr, Mn, Fe, Co, Ni, Nb, Ta, Mo, W, Re, Ru, and Rh, Z is at least one element selected from O, S, Se, N, Cl, Br, and I, and x falls in the range of 0.3≦x≦1.

□_{X}MZ₃ Chemical formula 3:

where □ is the vacant site in which the above-described X ion is accommodated, M is at least one element selected from Ti, V, Cr, Mn, Fe, Co, Ni, Nb, Ta, Mo, W, Re, Ru, and Rh, Z is at least one element selected from O, S, Se, N, Cl, Br, and I, and x falls in the range of 1≦x≦2.

□_{X}MZ₄ Chemical formula 4:

where □ is the vacant site in which the above-described X ion is accommodated, M is at least one element selected from Ti, V, Cr, Mn, Fe, Co, Ni, Nb, Ta, Mo, W, Re, Ru, and Rh, Z is at least one element selected from O, S, Se, N, Cl, Br, and I, and x falls in the range of 1≦x≦2.

□_{X}MPO_{Z} Chemical formula 5:

where □ is the vacant site in which the above-described X ion is accommodated, M is at least one element selected from Ti, V, Cr, Mn, Fe, Co, Ni, Nb, Ta, Mo, W, Re, Ru, and Rh, P is phosphorus element, O is oxygen element, x falls in the range of 0.3≦x≦3, and z falls in the range of 4≦z≦6.

□_{X}M₂Z₅ Chemical formula 6:

where □ is the vacant site in which the above-described X ion is accommodated, M is at least one element selected from V, Cr, Mn, Fe, Co, Ni, Nb, Ta, Mo, W, Re, Ru, and Rh, Z is at least one element selected from O, S, Se, N, Cl, Br, and I, and x falls in the range of 1≦x≦2.

In the above-described chemical formulas 2 to 6, the vacant site in which X ion is accommodated is expressed by □. However, in order to manufacture the layer of the second chemical compound 12B stably, part of the vacant site may be previously occupied by other ions.

Further, the second chemical compound adopts one of the following crystalline structures:

That is, hollandite structure, ramsdellite structure, anatase structure, brookite structure, pyrolusite structure, ReO₃ structure, MoO_{1.5}PO₄ structure, TiO_{0.5}PO₄ structure, FePO₄ structure, βMnO₂ structure, γMnO₂ structure, and λMnO₂ structure.

Further, the Fermi level of electrons of the first chemical compound is made lower than the Fermi level of electrons of the second chemical compound. This is one of the necessary conditions that reversibility is given to the state of the recording layer. Here, each Fermi level has a value measured from the vacuum level.

Note that, when using materials having the ramsdellite structure or hollandite structure as the second chemical compound, the degree of matching of lattice constants of the first chemical compound and the second chemical compound becomes high, which is preferable because it becomes possible to cause the second chemical compound to be aligned favorably.

By using the above recording layer, the recording density of Pbpsi class can be realized in principle, and further, it is possible to achieve a small power consumption.

### 2. Basic Principle of Recording/Reproducing

(1) An explanation will be made about the principle of recording/reproduction of information in the information recording/reproducing device according to the first example of the present invention.

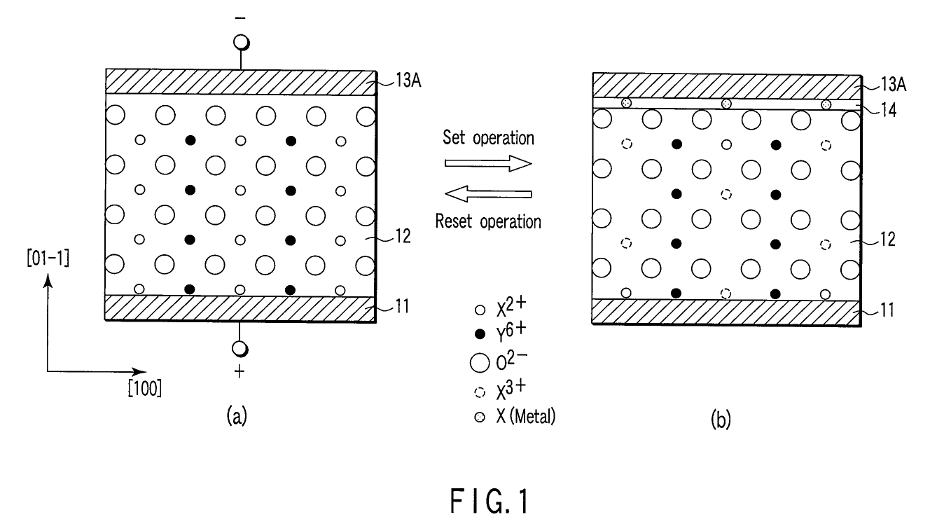

FIG. 1A shows a cross sectional view of the Wolframite structure of the recording section. The details of the Wolframite structure and Scheelite structure are described in, for instance, Y. Abraham et al. Physical Review B, vol. 62, p.p. 1733 to 1741 (2004).

Reference numeral 11 indicates an electrode layer, 12 indicates a recording layer, and 13A indicates an electrode layer (or protection layer). A big white circle indicates an O ion (oxygen ion), a small black circle indicates a Y ion, a small white circle indicates an X²⁺ ion, and a small white dotted circle indicates an X³⁺ ion. As shown in FIG. 1A, O ions, Y ions, and X ions are all positioned on a separated plane, and therefore it becomes possible to select an atomic species so that X ions can diffuse easily by application of an external electric field.

When applying a voltage to the recording layer 12 to generate a potential gradient in the recording layer 12, part of X ions diffuses within the crystal structure. Consequently, in the present invention, recording of information is performed in such a manner that the initial state of the recording layer 12 is arranged to be an insulator (high resistance state) phase, and potential gradient causes the phase change in the recording layer 12, so that conductivity is provided to the recording layer 12 (low resistance state phase).

Firstly, for instance, there is prepared a state where the electric potential of the electrode layer 13A is relatively lower than the electric potential of the electrode layer 11. It is only necessary to supply a negative electric potential to the electrode layer 13A when the electrode layer 11 has a fixed electric potential, for instance, ground potential.

At this time, part of X ions in the recording layer 12 moves to the electrode layer (cathode) 13A side, so that the number of X ions inside the recording layer (crystal) 12 decreases relatively to O ions. X ions having moved to the electrode layer 13A side receive electrons from the electrode layer 13A, and form a metal layer 14 after separating out as X atoms being metal. Therefore, since X ions are reduced and behave like a metal in the region close to the electrode layer 13A, its electric resistance largely decreases.

Inside the recording layer 12, O ions become excessive. As a result, the excess O ions increase the valence of the remaining X ions not diffused, which remaining X ions are indicated by small white circles (dotted line) in FIG. 1B. At this time, when selecting X ions so that the electric resistance decreases at the time its valence increases, both inside the metal layer 14 and inside the recording layer 12, the electric resistance decreases by movement of X ions. Accordingly, the recording layer changes to a low resistance state phase. That is, information recording (set operation) is completed.

The information reproduction can be performed easily by applying the voltage pulse to the recording layer 12 to detect the resistance of the recording layer 12. However, the amplitude of the voltage pulse needs to be a minute value to the degree that movement of X ions is not generated.

The above process is a kind of electrolysis, and thus it can be considered that an oxidizing agent is generated by electrochemical oxidation at the electrode layer (anode) 11 side, while a reducing agent is generated by electrochemical reduction at the electrode layer (cathode) 13A side.

For this reason, in order to return the low resistance state phase to the high resistance state phase, for instance, it is only necessary to prompt an oxidation-reduction reaction of the recording layer 12 by performing Joule-heating of the recording layer 12 with a large-current pulse. That is, X ions return to the interior of the thermally stabilized crystal structure 12 by Joule's heat due to the large-current pulse, and thus the initial high resistance state phase appears (reset operation).

Alternatively, it is possible to perform the reset operation by applying a voltage pulse of the opposed polarity to that of the set voltage pulse. That is, as in the set operation, it is only necessary to supply the positive electric potential to the electrode layer 13A, when the electrode layer 11 has the fixed electric potential. Then, X atoms in the vicinity of the electrode layer 13A become X ions after providing electrons to the electrode layer 13A, after which X ions return to the interior of the crystal structure 12 due to the potential gradient inside the recording layer 12. As a result, part of X ions whose valence increased by the set operation reduce their valence to the initial value and the recording layer changes into an initial high resistance state phase.

However, in order to put the operation principle to practical use, it should be confirmed that the reset operation does not occur at room temperature (securing sufficiently long retention time) and the power consumption of the reset operation is sufficiently small.

The former condition can be achieved by making the valence of X ions bivalent or more. In this manner, it is possible to avoid movement of X ions in the state of room temperature and no electric potential gradients. On the other hand, the voltage necessary for the set operation becomes large, if X ions are elements whose valence is trivalent or more. Therefore, in the worst case, collapse of the crystal may be caused. For this reason, the valence of X ions is preferably bivalent.

Further, the later condition can be achieved by finding the diffusion path of X ions by which X ions are capable of moving inside the recording layer (crystal) 12 without causing crystal collapse. As described already, in the Wolframite structure, X ions, Y ions and O ions are positioned on a separated planes. Therefore, diffusion of the ions inside the layer is generated easily, and thus the Wolframite structure is suitable for the use as such a recording layer 12.

Further, when all of X ions are diffused, it is not possible to fulfill the neutrality condition of its charge by only Y ions and O ions. Therefore, after a certain ratio of X ions diffuse, the further diffusion of X ions is prevented by Coulomb force. That is, since there is the upper limit in diffusion amount of X ions, and the upper limit in the number of X³⁺ ions contributing to low resistance, the resistance in the low resistance state becomes a relatively large value. As described above, the reset process is the process in which X ions are returned into the host structure 12 while adding heat to the recording layer. It is preferable that the resistance is larger in the low resistance state, because heat is generated efficiently and low power consumption becomes possible. For this purpose, Y ions are preferably in the state that the electrons are not included in the outer-shell orbital, and thus cannot become ions with a higher valence. That is, for example, Y ions are preferably hexavalent in the case of the element of the 6A-group, and pentavalent in the case of the element of the 5A-group.

In particular, in the case where the material having a Wolframite structure is used as the recording layer, since X ions, Y ions and O ions are placed on the separated planes and the diffusion path of X ions has a linear shape, there is an advantage that diffusion of X ions occurs easily.

Subsequently, explanation will be made about the stability of the host structure after X ions are diffused. In the diffusion of X ions and the accompanying resistance change phenomenon in FIG. 1, when X ions differ from Y ions, it is possible to suppress the simultaneous diffusion of X ions and Y ions and to suppress the diffusion of the cations in the continuous regions inside the crystal. Therefore, it is desirable that X ions and Y ions are each selected from a different atomic species. On the other hand, in the case where an oxide of a single molecule such as NiO is used, there is a possibility that Ni ions diffuse from the continuous region. Accordingly, it becomes difficult to maintain the original crystal structure stably in the region with a continuous deficiency of the ions. Therefore, in order to return diffused ions to the original position, large power consumption is necessitated because this is accompanied by a large change of the crystal structure.

Further, in the case where the valence of Y ions is large, a larger Coulomb repulsion acts on a minimal deviation from the crystal lattice site of Y ions. Therefore, the position of Y ions is hardly deviated from the crystal lattice site. Therefore, in the case where the valence of Y ions is large, X ions remaining inside the host structure without being diffused increase its valence, and move so as to neutralize the overall electrical characteristics, and further, Y ions exist with their position unchanged. Thereby, it is easy to maintain a stable host structure. That is, in the Wolframite structure, the valence of Y ions is large, so that it is easy to maintain a stable host structure. For this reason, it is preferable for Y to be Mo, or W, which is a hexavalent cation. Further, as described in FIG. 1, in the case where X ions fulfill the neutrality condition of its charge by changing its own valence after diffusion of X ions, there is not generated the change of the valence of Y ions with the accompanying resistance change. Generally, in the case where the valence is changed, since the bond distance to oxygen is changed, movement of Y ions is easy to be generated. Therefore, in order to maintain the base structure stably, it is preferable that there is no change of valence caused by the resistance change. In this point as well, the Y is preferably Mo, or W.

Further, since the stability of Y ions increases as the mass of Y ions becomes larger, the Y is more preferably W.

Subsequently, explanation will be made with respect to X ions. As described above, it is necessary for X ions to change their valence before and after the diffusion of X ions. Therefore, it is necessary for X to include a transition element, which is capable of taking various valences stably, and have a “d” orbit in which electrons are incompletely filled. Here, the transition elements having a “d” orbit in which the electrons are incompletely filled are the elements of 4A-group, 5A-group, 6A-group, 7A-group and 8-group.

Further, as described above, when X ions are bivalent, diffusion and thermal stability of X ions are fulfilled simultaneously. Therefore, X ions are preferably bivalent. Furthermore, since lighter mass diffuses more easily, it is preferable that Ti, V, Mn, Fe, Co, and Ni are used as X.

When one of the bivalent X ions diffuses, as shown in FIG. 1B, it is necessary for two X ions remaining at its surrounding area to become trivalent. Here, if X ions take tetravalent, one of X ions becomes tetravalent so that the neutrality condition of the charge may be fulfilled. In the latter case, however, the difference in ion radius increases excessively in comparison with the case of bivalent, and even when Y ions are selected so as to exist stably, it becomes difficult to stably maintain the structure after diffusion of X ions. Therefore, it is more preferable that X ions do not take a tetravalent state, so that X is preferably Fe, Co, or Ni. Generally, the energy necessary to convert the a bivalent ion into a trivalent ion is smaller than the energy necessary to convert the a trivalent ion into a tetravalent ion. Therefore, also from the viewpoint of the overall ionization energy, it is preferable that two X ions become trivalent ions.

Further, since the bivalent X ions have a tetra-coordinated configuration in the Wolframite structure, it is more preferable that X is Fe or Ni capable of taking the tetra-coordinated state stably. In the case where Fe is used as X, and W is used as the Y, the structure may be a Ferberite structure, which is similar to the Wolframite structure. However, the difference between the two structures is that the angle formed between the crystal axes differs by one degree. Accordingly, the same mechanism as that described by using FIG. 1 can be realized. Also in this case, lower power consumption and an increased thermal stability can be fulfilled simultaneously. Further, a Hubnerite structure is also similar to the Wolframite structure. Therefore, the “Wolframite structure and/or similar one” indicates a Wolframite structure, Ferberite structure, or Hubnerite structure.

Alternatively, considering that the energy (the third ionization energy) necessary for X ions to increase the valence is small, X is preferably Ti or V. In the case where these elements are used as X, diffusion becomes easy also, because the ion radius of these elements is large and diffusion path becomes large.

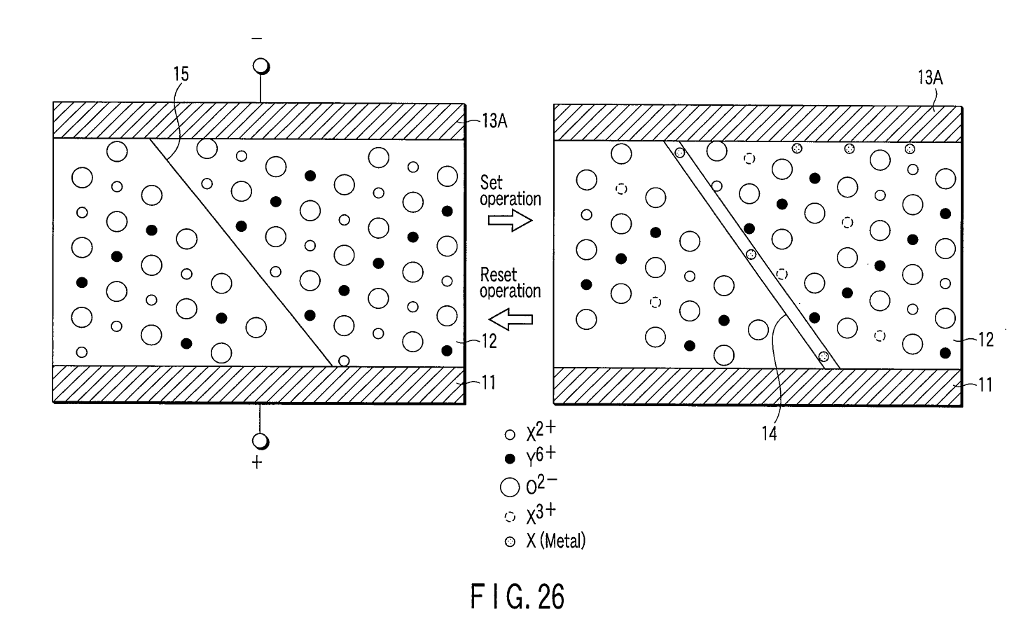

In FIG. 1, there is shown the case in which a sufficiently large crystal is obtained. However, as shown in FIG. 26, also in the case where the crystal has an arrangement being severed in the film thickness direction, movement of X ions and the accompanying resistance change can be generated by the mechanism described in the present invention.

That is, when adding a negative voltage to the electrode layer 13 with the electrode layer 11 earthed, the potential gradient is generated inside the recording layer 12, and X ions are transported. When X ions move to the crystal interface, X ions receive the electrons gradually from the region close to the electrode layer 13A, and behave like a metal. As a result, the metal layer 14 is formed in the vicinity of the crystal interface.

Further, in the recording layer 12, since the valence of the remaining X ions increases, its conductivity increases. In such a case, since a conductive path of the metal layer is formed along the crystal interface, the resistance between the electrode layer 11 and the electrode layer 13 decreases, so that the element changes into a low resistance state phase.

Also in this case, it is possible to change the low resistance state phase into a high resistance state phase by pulling X ions at the crystal interface back inside the crystal structure by Joule heating based on a large-current pulse, or by using the voltage pulse with the polarity opposed to that of the set voltage pulse.

However, in order that intercalation/de-intercalation of X ions as shown in FIG. 1 is to be efficiently generated to the voltage applied, it is preferable that the direction to which X ions diffuse and the direction to which the electric field is added are matched. As shown in FIG. 1, when “a” axis of the recording layer is oriented horizontally to a film surface of the recording layer, a diffusion path of X ions is arranged in the connecting direction between electrodes. Therefore, it is preferable that the “a” axis of the recording layer is oriented horizontally to the film surface. Also in the case where the “a” axis of the recording layer is oriented in the range of 45 degrees from level to the film surface of the recording layer, there is generated an electric field component along the diffusion direction of X ions, and therefore, it is possible to obtain the same effect.

Further, in the case where the crystal orientation of the recording layer is (01-1), the diffusion path of X ions is arranged in parallel with the electric field direction, and thus diffusion of X ions becomes easy. Therefore, it is more preferable since lower power consumption becomes possible.

Further, since the mobility of the ions differs between the inside of the crystal structure and the peripheral portion of the crystal grain, in order to equalize the recording/erase property at different cells by utilizing movement of the diffusion of ions inside the crystal structure, it is preferable that the recording layer is polycrystal or single crystal. When the recording layer is polycrystal, considering film-formability, it is preferable that the size of the crystal grains in the cross sectional direction of the recording film follows a distribution having a single peak, and its average is 3 nm or more. When the average of the crystal grain size is 5 nm or more, it is more preferable because film-formation is easier, while when the average of the crystal grain size is 10 nm or more, it is further more preferable because it is possible to further equalize the recording/erase property at different cells.

Finally, explanation will be made about the optimum value of the mixing ratio of the respective atoms. As described in FIG. 1, since the crystal structure can exist stably even in the state where X ions is lost, it is possible to optimize the mixing ratio of X ions so that the resistance of respective states or a diffusion coefficient of X ions becomes the optimum value. If the mixing ratio of X ions is too small, it becomes difficult to manufacture and maintain the crystal structure stably, while if the mixing ratio of X ions is too large, diffusion of the ions becomes difficult. Therefore, it is preferable that the mixing ratio “a” of X ions is 0.5≦a≦1.1. In order to suppress manufacturing unevenness, it is more preferable that the mixing ratio “a” of X ions is 0.7≦a≦1.0.

Since also for Y ions, the crystal structure can exist stably even though there is a certain degree of defect, it is preferable that the mixing ratio “b” of Y ions is 0.7≦b≦1.1. Further, in order to suppress the manufacturing unevenness, it is more preferable that the mixing ratio “b” of Y ions is 0.9≦b≦1. Here, the upper limit of Y ions is set to 1.1 in consideration of the fact that when there is the oxygen defect, the relative quantity of Y ions becomes large. However, in the case where Y ions exist on the diffusion path of X ions, diffusion of X ions becomes difficult. Therefore, it is preferable that the upper limit of Y ions is 1.0 when the oxygen defect is ignorable.

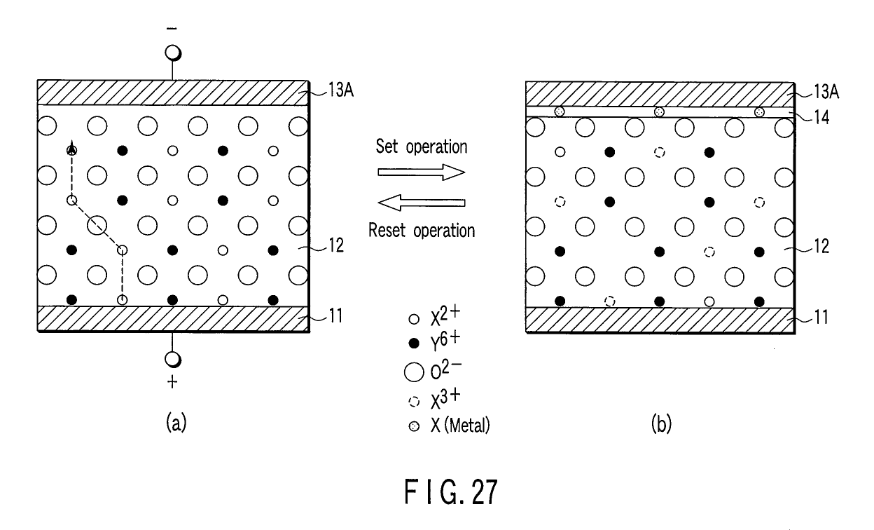

FIG. 27A shows a cross sectional view of the Scheelite structure of the recording section. Reference numeral 11 indicates an electrode layer, 12 indicates a recording layer, and 13A indicates an electrode layer (or protection layer). A big white circle indicates an O ion (oxygen ion), a small black circle indicates a Y ion, a small white circle indicates an X²⁺ ion, and a small white circle of dotted line indicates an X³⁺ ion. In FIG. 27A, since O ions exist on a plane other than X ions and Y ions, it becomes possible to select an atom species so that X ions can diffuse along a dotted line due to an external electric field.

When applying the voltage to the recording layer 12 to generate potential gradients in the recording layer 12, part of X ions moves inside the crystal. Consequently, in the present invention, recording of information is performed in such a manner that the initial state of the recording layer 12 is set to an insulator (high resistance state) phase, and potential gradients cause the phase change in the recording layer 12, so that conductivity is provided to the recording layer 12 (low resistance state phase).

Firstly, for instance, there is prepared a state where the electric potential of the electrode layer 13A is relatively lower than the electric potential of the electrode layer 11. It is only necessary to supply a negative electric potential to the electrode layer 13A when the electrode layer 11 has a fixed electric potential, for instance, ground potential.

At this time, part of X ions inside the recording layer 12 moves to the electrode layer (cathode) 13A side, so that X ions inside the recording layer (crystal) 12 decrease relatively to O ions. X ions having moved to the electrode layer 13A side receive electrons from the electrode layer 13A, and form a metal layer 14 after separating out as X atoms being metal. Therefore, since X ions are reduced and behave like a metal in the region close to the electrode layer 13A, its electric resistance largely decreases.

Inside the recording layer 12, O ions become excessive. As a result, the excess O ions increase the valence of the remaining X ions not diffused, which remaining X ions are indicated by small white circles (dotted line) in FIG. 27B. At this time, when selecting X ions so that the electric resistance decreases at the time its valence increases, both inside the metal layer 14 and inside the recording layer 12, the electric resistance decreases by movement of X ions. Accordingly, the recording layer changes to low resistance state phase. That is, information recording (set operation) is completed.

The information reproduction can be performed easily by applying the voltage pulse to the recording layer 12 to detect the resistance value of the recording layer 12. However, the amplitude of the voltage pulse needs to be a minute value to the degree that movement of X ions is not generated.

The above process is a kind of electrolysis, and thus it can be considered that an oxidizing agent is generated by electrochemical oxidation at the electrode layer (anode) 11 side, while a reducing agent is generated by electrochemical reduction at the electrode layer (cathode) 13A side.

For this reason, in order to return the low resistance state phase to the high resistance state phase, for instance, it is only necessary to prompt oxidation-reduction reaction of the recording layer 12 by performing Joule-heating of the recording layer 12 with a large-current pulse. That is, X ions return to the interior of the thermally stabilized crystal structure 12 by Joule's heat due to the large-current pulse, and thus the initial high resistance state phase appears (reset operation).

Alternatively, it is possible to perform the reset operation by applying a voltage pulse of the opposed polarity to that of the set voltage pulse. That is, as in the set operation, it is only necessary to supply the positive electric potential to the electrode layer 13A when the electrode layer 11 has the fixed electric potential. Then, X atoms in the vicinity of the electrode layer 13A become X ions after providing electrons to the electrode layer 13A, after which X ions return to the interior of the crystal structure 12 due to the potential gradients inside the recording layer 12. As a result, part of X ions with the increased valence change into an initial high resistance state phase, because its valence decreases into the same value as the initial state.

However, in order to put the operation principle to practical use, it should be confirmed that the reset operation does not occur at room temperature (securing sufficiently long retention time), and the power consumption of the reset operation is sufficiently small.

The former condition can be achieved by making the valence of X ions bivalent or more. In this manner, it is possible to avoid movement of X ions in the state of room temperature and no electric potential gradients. On the other hand, the voltage necessary for the set operation becomes large, if X ions are elements whose valence is trivalent or more. Therefore, in the worst case, collapse of the crystal may be caused. For this reason, the valence of X ions is preferably bivalent.

Further, the later condition can be achieved by finding the diffusion path of X ions by which X ions are capable of moving inside the recording layer (crystal) 12 without causing crystal collapse. As described already, in the Scheelite structure, there exists a diffusion path of X ions along the dotted line. Therefore, diffusion of the ions inside the layer is generated easily, and thus the Scheelite structure is suitable for the use as such a recording layer 12.

Further, when all of X ions are diffused, it is not possible to fulfill the neutrality condition of its charge by only Y ions and O ions. Therefore, after a certain ratio of X ions diffuse, the further diffusion of X ions is prevented by Coulomb force. That is, since there are the upper limit in diffusion amount of X ions, and the upper limit in the number of X³⁺ ions contributing to low resistance, the resistance in the low resistance state becomes a relatively large value. As described above, the reset process is the process in which X ions are returned into the host structure 12 while adding heat to the recording layer. It is preferable that the resistance is larger in the low resistance state, because heat is generated efficiently and low power consumption becomes possible.

Subsequently, explanation will be made about the stability of the host structure after X ions are diffused. In the diffusion of X ions and the accompanying resistance change phenomenon in FIG. 1, in the case where the valence of Y ions is large, a larger Coulomb repulsion force acts on a minimal deviation from the crystal lattice site of Y ions. Therefore, the position of Y ions is hardly deviated from the crystal lattice site. Therefore, in the case where the valence of Y ions is large, X ions remaining inside the host structure without being diffused increase its valence, and move so as to neutralize the overall electrical characteristics, and further, Y ions exist with its position unchanged. Thereby, a stable host structure can be maintained easily. That is, in the Scheelite structure, the valence of Y ions is large, so that a stable host structure is easy to maintain. For this reason, it is preferable that Y ions are Mo, or W, which is hexavalent cation. Further, as described in FIG. 27, in the case where X ions fulfill the neutrality condition of the electric charges by changing its own valence after diffusion of X ions, there is not generated the change of the valence of Y ions with the accompanying resistance change. Generally, in the case where the valence is changed, the bond distance to oxygen is changed, and therefore, movement of Y ions easily occurs. Therefore, in order to maintain the host structure stably, it is preferable that there is no change of valence of Y ions caused by the resistance change. In this regard as well, it is preferable that the Y is Mo, or W.

Further, since the stability of Y ions increases as the mass of Y ions becomes larger, it is more preferable that for the Y to be W.

Subsequently, explanation will be made with respect to X ions. As described above, it is necessary for X ions to change their valence before and after the diffusion of X ions. Therefore, it is necessary for X to include a transition element, which is capable of taking various valences stably, having a “d” orbit where electrons are incompletely filled. Here, the transition elements having a “d” orbit in which the electrons are incompletely filled are the elements of 4A-group, 5A-group, 6A-group, 7A-group and 8-group.

Further, as described above, when X ions are bivalent, since diffusion and thermal stability of X ions are fulfilled simultaneously, it is preferable that X ions are bivalent. Furthermore, since a lighter mass diffuses more easily, it is preferable that Ti, V, Mn, Fe, Co, and Ni are used as X.

When one of the bivalent X ions diffuses, as shown in FIG. 27B, it is necessary for two X ions remaining at its surrounding area to become trivalent. Here, if X ions may take tetravalent, also one of X ions becomes tetravalent so that the neutrality condition of the charge may be fulfilled. In the latter case, however, the difference in ion radius increases excessively in comparison with the case of bivalence, and even when Y ions are selected so as to exist stably, it becomes difficult to stably maintain the structure after diffusion of X ions. Therefore, it is more preferable that X ions do not take tetravalent, so that it is preferable for X to be Fe, Co, or Ni. Generally, the energy necessary to convert a bivalent ion into a trivalent ion is smaller than the energy necessary to convert a trivalent ion into a tetravalent ion. Therefore, also from the viewpoint of the overall ionization energy, it is preferable that two X ions become trivalent ions.

In the Scheelite structure where the diffusion path of X ions exists in a nonlinear shape, the easiness to diffuse X ions is largely unaffected by the direction of the crystal axis. Therefore, even when the direction of the crystal axis cannot be controlled sufficiently at the time of manufacturing, the Scheelite structure has an advantage that characteristic unevenness according to cells can be minimized.

Further, in the Scheelite structure, since the diffusion path of X ions is in a nonlinear shape, diffusion quantity of X ions hardly becomes excessive, and the number of X³⁺ contributing to low resistance hardly becomes excessive. Accordingly, it is possible to make the resistance value in the state of low resistance a relatively large value. Therefore, at the time of the reset, joule-heating occurs effectively, and thus it is possible to expect realization of low power consumption at the time of the reset.

Finally, explanation will be made about the optimum value of the mixing ratio of the respective atoms. As described in FIG. 1, since the crystal structure can exist stably even in the state where an X ion has some defects, it is possible to optimize the mixing ratio of X ions so that resistance of respective states or a diffusion coefficient of X ions becomes the optimum value. If the mixing ratio of X ions is too small, it becomes difficult to manufacture and maintain the crystal structure stably, while if the mixing ratio of X ions is too large, diffusion of the ions becomes difficult. Therefore, it is preferable for the mixing ratio “a” of X ions to be 0.5≦a≦1.1. In order to suppress manufacturing unevenness, it is more preferable for the mixing ratio “a” of X ions to be 0.7≦a≦1.0.

Since also for Y ions, the crystal structure can exist stably even though there is a certain degree of defects, it is preferable for the mixing ratio “b” of Y ions to be 0.7≦b≦1.1. Further, in order to suppress the manufacturing unevenness, it is more preferable for the mixing ratio “b” of Y ions to be 0.9≦b≦1. Here, the upper limit of Y ions is set to 1.1 in consideration of the fact that when there is an oxygen defect, the relative quantity of Y ions becomes large. However, in the case where Y ions exist on the diffusion path of X ions, diffusion of X ions becomes difficult. Therefore, it is preferable for the upper limit of Y ions to be 1.0 if the oxygen defect is ignorable.

As structures similar to the Scheelite structure, there are a Stolzite structure, Wulfenite structure and the like, in addition to the Scheelite structure.

Meanwhile, both in the case of a “Wolframite structure and/or similar one” shown in FIG. 1 and in the case of a “Scheelite structure and/or similar one” shown in FIG. 27, the oxidizing agent is generated in the electrode layer (anode) 11 side after the set operation. Therefore, it is preferable that the electrode layer 11 be comprised a material which is hardly oxidized (for instance, electrically-conductive nitride, and electrically-conductive oxide). Further, such a material preferably has no ion conductivity.

The materials with the above property are as follows. Among them, from the viewpoint of comprehensive performance coupled with good electrical conductivity, LaNiO₃ is the most preferable material.

.MN

M is at least one element selected from the group of Ti, Zr, Hf, V, Nb, Ta, Mo, and W. N is nitrogen.

.MO_{X}

M is at least one element selected from the group of Ti, V, Cr, Mn, Fe, Co, Ni, Cu, Zr, Nb, Mo, Ru, Rh, Pd, Ag, Hf, Ta, W, Re, Ir, Os, and Pt. Molar ratio x fulfills 1≦x≦4.

.AMO₃

A is at least one element selected from the group of La, K, Ca, Sr, Ba, and Ln (Lanthanide).

M is at least one element selected from the group of Ti, V, Cr, Mn, Fe, Co, Ni, Cu, Zr, Nb, Mo, Ru, Rh, Pd, Ag, Hf, Ta, W, Re, Ir, Os, and Pt.

O is oxygen.

.A₂MO₄

A is at least one element selected from the group of K, Ca, Sr, Ba, and Ln (Lanthanide).

M is at least one element selected from the group of Ti, V, Cr, Mn, Fe, Co, Ni, Cu, Zr, Nb, Mo, Ru, Rh, Pd, Ag, Hf, Ta, W, Re, Ir, Os, and Pt.

O is oxygen.

Alternatively, there may be provided a buffer layer to control the orientation of the recording layer between the recording layer and the electrode layer 11. Preferable examples of the material used as the buffer layer include oxide of Ir or Ru, or nitride of Si, Ti, Zr, Hf, V, Nb, Ta, or W. Further, it is more preferable that the buffer layer is oriented so as that the ratio lr/lb is close to n or 1/n where n is an integer, preferably less than 5, and lr and lb are the lattice constant of the recording layer and the buffer layer when the recording layer is oriented in a required direction. Preferable examples thereof include the nitride of Ti, V, W, Zr, or Hf which is (100) oriented.

Further, the reducing agent is generated in the protection layer (cathode) 13 side after the set operation. Therefore, it is preferable that the protection layer 13 has a function of preventing the recording layer 12 from reacting with atmospheric air.

Examples of such a material include a semiconductor such as amorphous carbon, diamond-like carbon, and SnO₂.

The electrode layer 13A may function as the protection layer to protect the recording layer 12, or the protection layer may be provided instead of the electrode layer 13A. In this case, the protection layer may be an insulator or a conductive material.

Further, in order to efficiently perform heating of the recording layer 12 in the reset operation, a heater layer (material having resistivity of approximately 10⁻⁵ Ωcm or more) may be provided at the cathode side, in this case at the electrode layer 13A side.

(2) Explanation will be made about a basic principle of recording/erase/reproduction of information in the information recording/reproducing device according to the second example of the present invention.

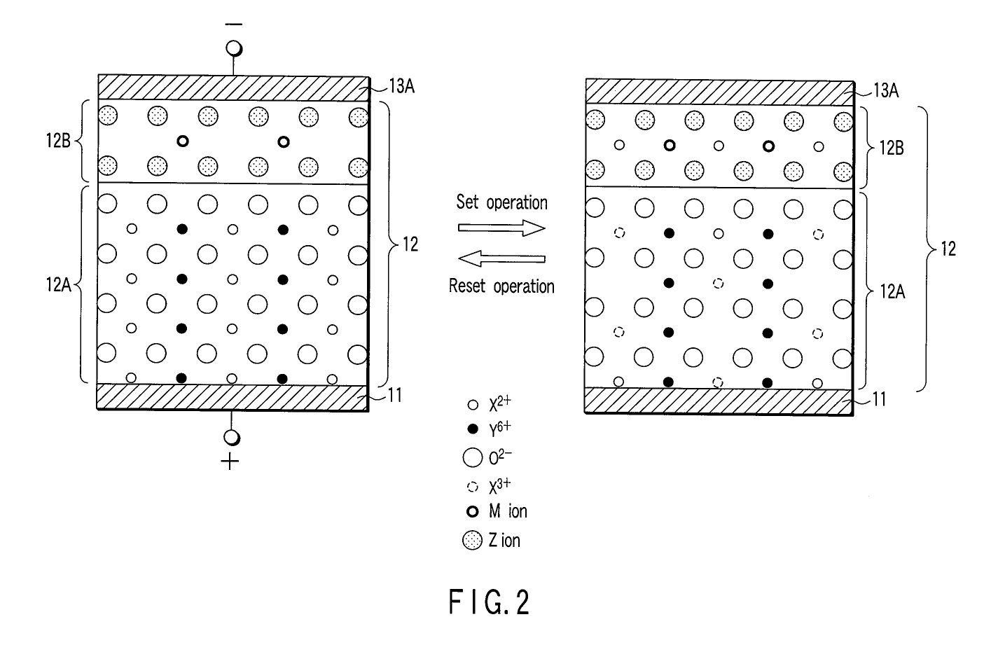

FIG. 2 shows a structure of the recording section.

Reference numeral 11 indicates an electrode layer, 12 indicates a recording layer, and 13A indicates an electrode layer (or protection layer).

The recording layer 12 arranged at the electrode layer 11 side is comprised a first chemical compound 12A having the “Wolframite structure and/or similar one” or the “Scheelite structure and/or similar one”, and a second chemical compound 12B arranged at the electrode layer 13A side and having an vacant site capable of accommodating cation elements.

Big white circles inside the first chemical compound 12A indicate O ions (oxygen ions), small black circles indicate Y ions, small white circles indicate X²⁺ ions, and small white circles of dotted lines indicate X³⁺ ions. Further, small white circles inside the second chemical compound 12B indicate X ions, white circles with bold lines indicate M ions, and big white circles filled with dots indicate Z ions.

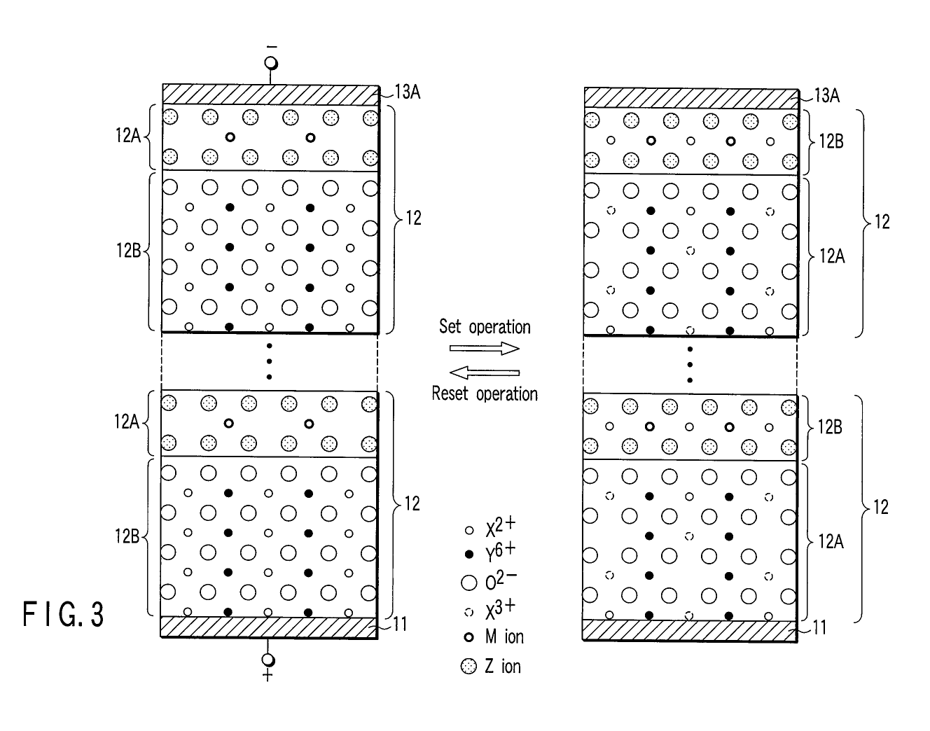

Note that, as shown in FIG. 3, the first chemical compound 12A and the second chemical compound 12B constituting the recording layer 12 may be respectively stacked into plural layers of two layers or more.

In such a recording section, when potential gradients are caused to be generated inside the recording layer 12 by applying an electric potential to the electrode layers 11, 13A so that the first chemical compound 12A becomes the anode side, and the second chemical compound 12B becomes the cathode side, part of X²⁺ ions inside the first chemical compound 12A moves through the crystal and enter the second chemical compound 12B of the cathode side.

Since there is a vacant site capable of accommodating X ions in the crystal of the second chemical compound 12B, X ions moved from the first chemical compound 12A become accommodated in the vacant sites.

Therefore, in the first chemical compound 12A, the valence of X ions undiffused is elevated to become X³⁺ ions. On the contrary, in the second chemical compound 12B, the valence of M ions decreases. Therefore, it is preferable that M ions are the ions comprised transition elements. Further, when considering easiness of control of the electronic characteristic, it is preferable that at least one element selected from Ti, V, Cr, Mn, Fe, Co, Ni, Nb, Ta, Mo, W, Re, Ru, and Rh be used as the M. Furthermore, from the viewpoint of easiness of film formation, it is preferable that O (oxygen) be used as the Z.

That is, assuming that both of the first and second chemical compounds 12A, 12B are initially in the high resistance state (insulator), part of X ions inside the first chemical compound 12A enter the second chemical compound 12B, thereby generating conductive carriers inside the crystal of the first and second chemical compounds 12A, 12B to impart electrical conductivity to both the compounds.

Thus, by providing a current/voltage pulse to the recording layer 12, the electric resistance value of the recording layer 12 decreases to realize the set operation (recording).

At this time, simultaneously, the electrons move toward the second chemical compound 12B from the first chemical compound 12A. However, since the Fermi level of the electrons of the second chemical compound 12B is higher than the Fermi level of the electrons of the first chemical compound 12A, the total energy of the recording layer 12 increases.

Further, after the set operation is completed, such a high energy state is continued. Therefore, there is a possibility that the recording layer 12 naturally returns to the reset state (high resistance state) from the set state (low resistance state).

However, if the recording layer 12 according to the example of the present invention is used, such worry is avoided. That is, it is possible to continue the set state.

This is due to so called transfer resistance of the ions.

The valence of X ions inside the first chemical compound 12A provides this action. That the valence is bivalent is of key importance.

Assuming that X ions are monovalent elements such as Li ions, sufficient transfer resistance of the ions cannot be obtained in the set state, and X ions immediately return to the first chemical compound 12A from the second chemical compound 12B. In other words, a sufficiently long retention time cannot be obtained.

Further, if X ions are elements whose valence is trivalent or more, the voltage necessary for the set operation becomes large. Therefore, in the worst case, collapse of the crystal may be caused.

Therefore, that the valence of X ions is bivalent becomes preferable as the information recording/reproducing device.

Further, since the oxidizing agent is generated at the anode side after completing the set operation, also in this case, it is preferable that the electrode layer 11 is comprised a material which is hardly oxidized and has no ion conductivity (for instance, electrically-conductive oxide). Preferable examples thereof are described above.

It is only necessary for the reset operation (erase) to facilitate the phenomenon in which X ions accommodated inside the vacant site of the above-described second chemical compound 12B return to the first chemical compound 12A while heating the recording layer 12.

Specifically, when utilizing Joule's heat generated by providing a large-current pulse to the recording layer 12 and its residual heat, it is possible to easily return the recording layer 12 to the original high resistance state (insulator).

Thus, since the electrical resistance value of the recording layer 12 becomes large by providing the large-current pulse to the recording layer 12, the reset operation (erase) is realized. Alternatively, it is also possible to perform the reset operation by applying an electric field of inverse direction to the set operation.

Here, in order to realize low power consumption, it becomes important to optimize the ion radius of X ions, and to use the structure in which the diffusion path exists so that X ions can move inside the crystal without causing crystal breakdown.

In the case where the material and the crystal structure described in the item of the outline are used as the second chemical compound 12B, such conditions are fulfilled, and the above case is effective for realizing low power consumption. In particular, the oxides such as V, Ti, and W are widely known for cation diffusion and the accompanying change of conductivity, and thus these oxides are preferably used as the second chemical compound.

Further, movement of cations is easily generated inside the first chemical compound having the “Wolframite structure and/or similar one” or the “Scheelite structure and/or similar one”, and thus such structure is preferably used as the first chemical compound.

Explanation will next be made about the preferable range of film thickness of the second chemical compound.

In order to obtain an effect of X ions accommodation due to the vacant site, it is preferable that the film thickness of the second chemical compound be 1 nm or more.

On the other hand, when the number of the vacant sites of the second chemical compound becomes larger than the number of X ions inside the first chemical compound, the resistance change effect of the second chemical compound becomes small. Therefore, it is preferable for the number of the vacant sites inside the second chemical compound to be the same as or smaller than the number of X ions inside the first chemical compound residing inside the same cross sectional area.

Since the density of X ions inside the first chemical compound is basically the same as the density of the vacant sites inside the second chemical compound, the film thickness of the second chemical compound is preferably the same as or smaller than the thickness of the first chemical compound.

Generally, in order to further facilitate the reset operation, a heater layer (material having resistivity of approximately 10⁻⁵ Ωcm or more) may be provided at the cathode side.

In a probe memory, because a reducing material separates out at the cathode side, it is preferable to provide a surface protection layer for blocking the reaction with atmospheric air.

It is also possible to constitute the heater layer and the surface protection layer with one material having both functions. For instance, a semiconductor such as amorphous carbon, diamond-like carbon, or SnO₂ has the heater function in conjunction with the surface protection function.

The reproduction is easily performed by detecting the resistance value of the recording layer 12 while causing the current pulse to flow through the recording layer 12.

However, the current pulse needs to have a minute value to the degree that the material constituting the recording layer 12 does not cause a resistance change.

### 3. Embodiments

Next, explanation will be made on some embodiments considered to be the best.

Hereinafter, explanation will made about two cases: a first case in which the example of the present invention is applied to a probe memory and a second case in which the example of the present invention is applied to a semiconductor memory.

(1) Probe Memory

A. Structure

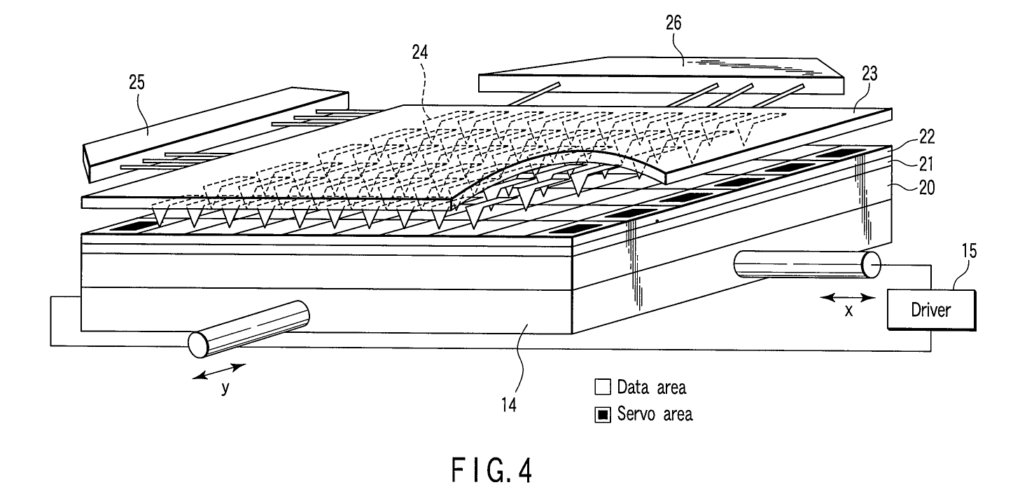

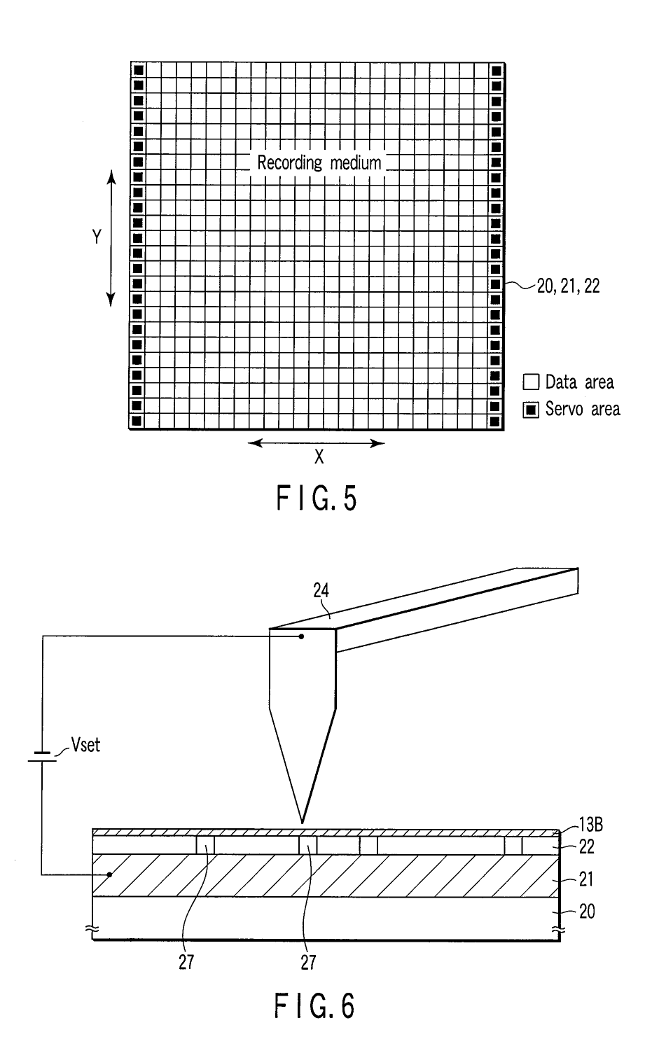

FIGS. 4 and 5 show the probe memory according to the example.

A recording medium is arranged on an XY scanner 14. A probe array is arranged to face the recording medium.

The probe array has a substrate 23 and a plurality of probes (heads) 24 arranged in an array shape at one face side of the substrate 23. Each of the plurality of probes 24 is comprised by, for instance, a cantilever, and driven by multiplex drivers 25, 26.

Each of the plurality of probes 24 can operate individually by using a micro actuator in the substrate 23. However, here, there will be explained an example in which access is performed to data areas of the recording medium while causing all the probes to operate in the same manner.

Firstly, by using the multiplex drivers 25, 26, all the probes 24 are caused to perform a reciprocating operation at a constant frequency in the X direction, to read position information of the Y direction from a servo area of the recording medium. The position information in the Y direction is transferred to a driver 15.

The driver 15 drives the XY scanner 14 based on the position information, causes the recording medium to move in the Y direction, and performs positioning of the recording medium and the probe.

After completing the positioning of the both, read or write of data is performed simultaneously and continuously to all the probes 24 on the data area.

The read and write of the data are performed continuously because the probe 24 is performing the reciprocating operation in the X direction. Further, the read and write of the data are executed in every one line to the data area by sequentially changing the position in the Y direction of the recording medium.

Meanwhile, it is also possible to read the position information from the recording medium while causing the recording medium to perform reciprocating movement at a constant frequency in the X direction, and then cause the probe 24 to move in the Y direction.

The recording medium is comprised, for instance, a substrate 20, an electrode layer 21 on the substrate 20, and a recording layer 22 on the electrode layer 21.

The recording area 22 has a plurality of data areas, and servo areas arranged respectively at both ends in the X direction of the plurality of the data areas. Data areas occupy a principal part of the recording layer 22.

Servo burst signals are recorded in the servo area. The servo burst signals indicate the position information in the Y direction in the data area.

In the recording layer 22, in addition to these pieces of information, there are arranged an address area in which address data is recorded and a preamble area to take synchronization.

The data and the servo burst signal are recorded in the recording layer 22 as recording bits (the electric resistance change).

“1”, “0” information of the recording bit is read by detecting the electric resistance of the recording layer 22.

In the present example, one probe (head) corresponding to one data area is provided, and one probe corresponding to one servo area is provided.

The data area is comprised by a plurality of tracks. The track of the data area is specified by address signals read from the address area. Further, the servo burst signal read from the servo area is for causing the probe 24 to move to the center of the track to eliminate read error of the recording bit.

Here, the X direction is caused to correspond to a down track direction, and the Y direction is caused to correspond to an up track direction, thereby making it possible to utilize the head position control technique of HDD.

B. Recording/Reproducing Operation

Explanation will next be made about recording/reproducing operation of the probe memory of FIGS. 4 and 5.

FIG. 6 shows a state at the time of recording (set operation).

The recording medium is comprised the electrode layer 21 on the substrate (for instance, semiconductor chip) 20, the recording layer 22 on the electrode layer 21, and the protection layer 13B on the recording layer 22. The protection layer 13B is comprised, for instance, a thin insulating material.

A recording operation is performed by generating the potential gradients in a recording bit 27 by applying a voltage to a surface of the recording bit 27 of the recording layer 22. Specifically, it is only necessary to supply a current/voltage pulse to the recording bit 27.

First Example

The first example is a case where the materials of FIG. 1 are used for the recording layer.

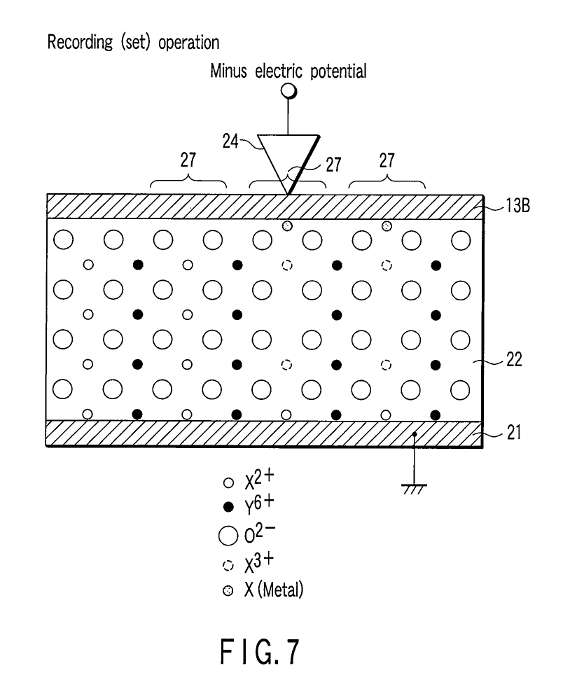

Firstly, as shown in FIG. 7, there is prepared a state where the electric potential of the probe 24 is relatively lower than the electric potential of the electrode layer 21. The probe 24 may be supplied with a negative electric potential, when the electrode layer 21 has a fixed electric potential, for instance, ground potential.

The current pulse is generated by emitting electrons toward the electrode layer 21 from the probe 24 while using, for instance, an electron generating source or hot electron source. Alternatively, it is also possible to bring the probe 24 into contact with the surface of the recording bit 27 to apply the voltage pulse.

At this time, for instance, in the recording bit 27 of the recording layer 22, part of X ions moves to the probe (cathode) 24 side, and the number of X ions inside the crystal relatively decreases in comparison to the number of O ions. Further, X ions moved to the probe 24 side separate out as the metal, while receiving electrons from the probe 24.

In the recording bit 27, O ions become excessive, resulting in an increase in valence of X ions in the recording bit 27. That is, the recording bit 27 comes to have electron conductivity due to implantation of carrier by phase change, thereby decreasing the resistance in the thickness direction, and then the recording (set operation) is completed.

Similarly, the current pulse for recording can also be generated by preparing the state where the electric potential of the probe 24 is relatively higher than the electric potential of the electrode layer 21.

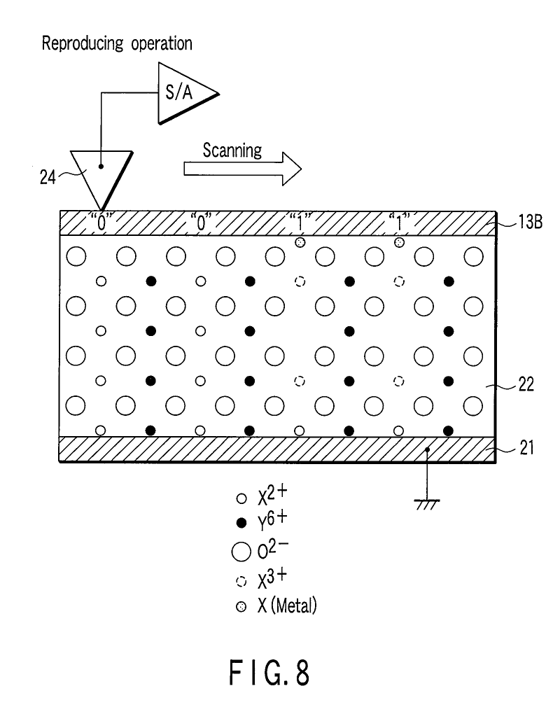

FIG. 8 shows the reproduction.

The reproduction is performed by causing the current pulse to flow through the recording bit 27 of the recording layer 22, followed by detecting the resistance value of the recording bit 27. However, the current pulse is set to a minute value to the degree that the material constituting the recording bit 27 of the recording layer 22 does not cause the resistance change.

For instance, a read current (current pulse) generated by a sense amplifier S/A is caused to flow through the recording bit 27 from the probe 24, and then, the resistance value of the recording bit 27 is measured by the sense amplifier S/A.

If the material according to the example of the present invention is used, it is possible to secure a difference of 10³ or more in the resistance value between the set/reset states.

Meanwhile, in the reproduction, continuous reproduction becomes possible by scanning the recording medium by the probe 24.

The erase (reset) operation is performed by promoting the oxidation-reduction reaction in the recording bit 27 in such a manner that the recording bit 27 of the recording layer 22 is subjected to joule heating based on the large-current pulse. Alternatively, it is also possible to apply the pulse providing potential of an inverse direction to the potential difference at the time of the set operation.

The erase operation can be performed in every recording bit 27, or can be performed on a plurality of recording bits 27 or on a block unit.

Second Example

The second example shows a case where the materials of FIG. 2 are used for the recording layer.

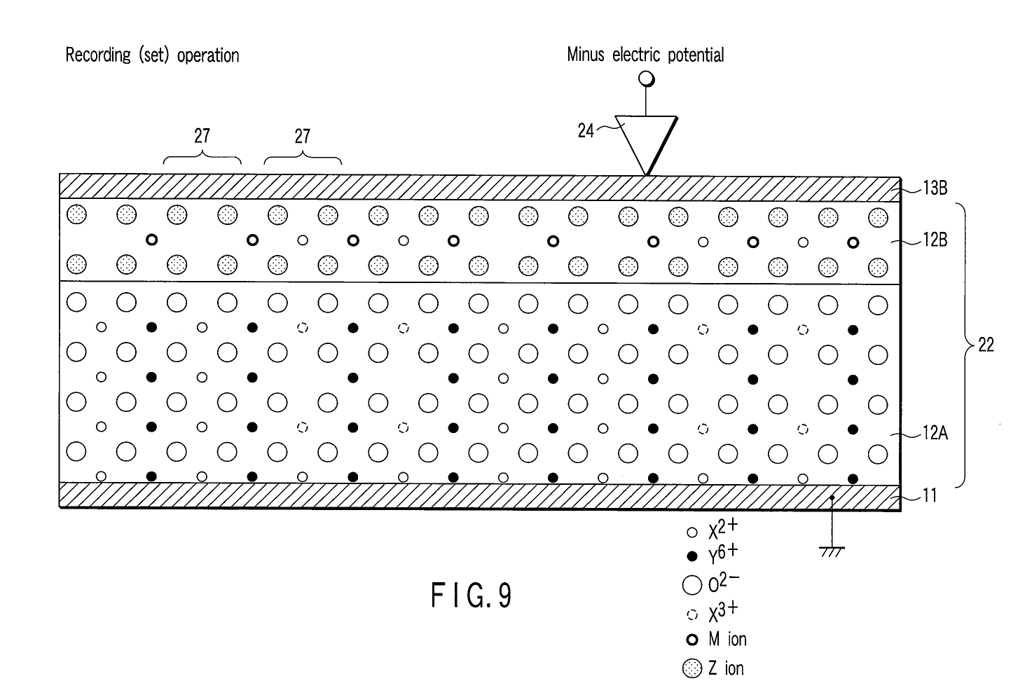

Firstly, as shown in FIG. 9, there is prepared a state where the electric potential of the probe 24 is relatively lower than the electric potential of the electrode layer 21. It is only necessary to supply a negative potential to the probe 24 when the electrode layer 21 has a fixed electric potential, for instance, ground potential.

At this time, part of X ions inside the first chemical compound (anode side) 12A of the recording layer 22 is accommodated in the vacant site of the second chemical compound (cathode side) 12B while moving inside the crystal. With this, the valence of X ions inside the first chemical compound 12A increases, while the valence of M ions inside the second chemical compound 12B decreases. As a result, conductive carriers are generated inside the crystal of the first and second chemical compounds 12A, 12B, and then both come to have the electrical conductivity.

In this manner, the set operation (recording) is completed.

Meanwhile, concerning the recording operation, assuming that the position relation of the first and second chemical compounds 12A, 12B is reversed, it is also possible to execute the set operation while making the electric potential of the probe 24 relatively higher than the electric potential of the electrode layer 21.

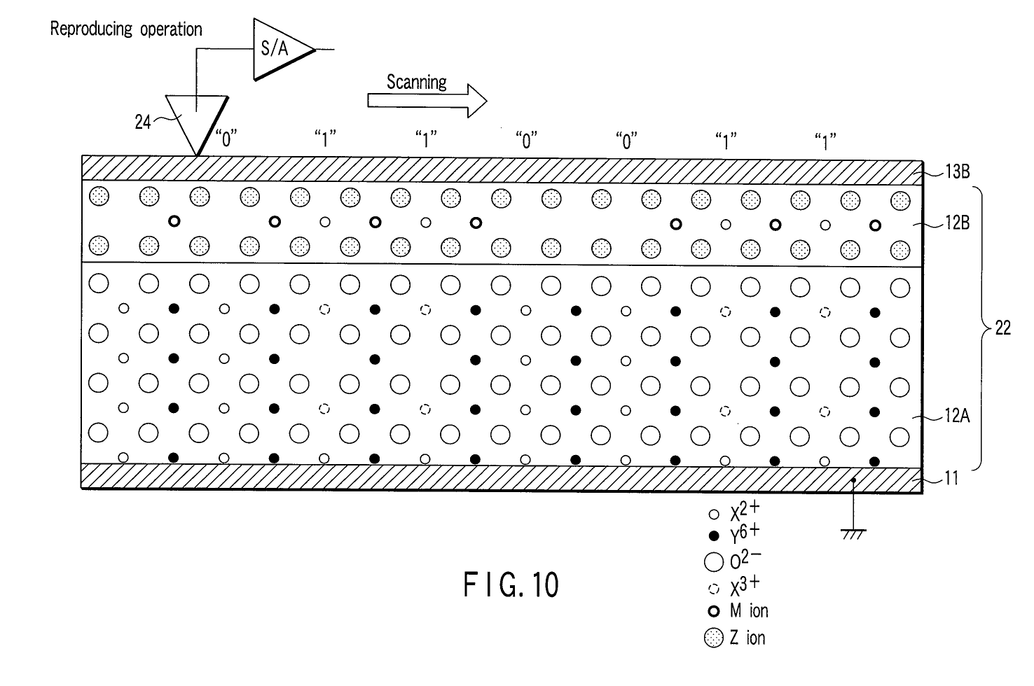

FIG. 10 shows a state at the time of the reproduction.

The reproducing operation is performed by causing the current pulse to flow through the recording bit 27, followed by detecting the resistance value of the recording bit 27. However, the current pulse needs to have a minute value to the degree that the material constituting the recording bit 27 does not cause the resistance change.

For instance, the read current (current pulse) generated by the sense amplifier S/A is caused to flow through the recording layer (recording bit) 22 from the probe 24, and then, the resistance value of the recording bit is measured by the sense amplifier S/A. When adopting the new materials described already, it is possible to secure a difference of 10³ or more in the resistance value between the set/reset states.

Meanwhile, the reproducing operation can be performed continuously by scanning the probe 24.

The reset (erase) operation may be performed by facilitating the action in which X ions return to first chemical compound 12A from the vacant site inside the second chemical compound 12B while utilizing the joule heat and its residual heat generated by causing the large-current pulse to flow through the recording layer (recording bit) 22. Alternatively, it may be performed by applying the pulse providing the potential difference in an inverse direction to the potential difference at the time of the set operation.

The erase operation can be performed in every recording bit 27, or can be performed on a plurality of recording bits 27 or on a block unit.

C. Experiment Example

The recording medium having the structure shown in FIG. 7 is used as a sample, and evaluation may be performed by using a pair of acicular probes whose diameter of a leading edge is 10 nm or less.

The electrode layer 21 is, for instance, a Pt film formed on a semiconductor substrate. In order to increase adhesion properties between the semiconductor substrate and a lower electrode, Ti of about 5 nm may be used as an adhesion layer. The recording layer 22 can be obtained by performing RF magnetron sputtering on a disk in a mixed gas of argon and oxygen while maintaining the temperature of the disk at a high temperature of about 600° C., by using a target in which components are adjusted so as to have the desired composition. Further, as the protection layer, for instance, diamond-like carbon may be formed by the CVD method. The film thickness of the respective layers can be designed so as to optimize a resistance ratio between the low resistance state and the high resistance state, required energy for switching, switching speed, and the like. For instance, the required film thickness can be obtained by adjusting the sputtering time.

The write/erase is executed by bringing one of the probe pair into contact with the protection layer 13B to earth, and the other of the probe pair is caused to come into contact with the lower electrode layer. For instance, the write is performed by applying the voltage pulse of 1V with a width of 50 nsec to the recording layer 22. On the other hand, for instance, the erase can be performed by applying the voltage pulse of 0.2V with a width of 200 nsec to the recording layer 22.

Further, the read is executed by using the probe pair between an interval of the write/erase. The read can be performed by measuring the resistance value of the recording layer (recording bit) 22 while applying the voltage pulse of 0.1V with a width of 10 nsec to the recording layer 22.

For instance, in the case where NiWO₄ having the Wolframite structure is used as the recording layer, since Ni ions, W ions, and O ions exist with a layered shape, there is the diffusion path of linearly arranged Ni ions, and thus the diffusion of the Ni ions is generated efficiently. Further, after diffusion of the Ni ions, the valence of the Ni ions remaining inside the recording layer increases to trivalent, and accordingly, a lower resistance state of the recording layer can be realized. At this time, the hexavalent W ions with large atomic mass do not change their valence, irrespective of the existence of Ni ions, and do not change their bond length to O ions. Therefore, the crystal structure is easily maintained stably after the Ni ions are diffused. Further, in order to fulfill the neutrality condition of the electric charge, not all of the Ni ions can diffuse. Therefore, the resistance in the low resistance state does not become excessively small, and it is possible to make smaller the power required for switching, and the diffusion of the Ni ions to be easily generated. Further, since the bivalent Ni ions easily take a tetra-coordinated structure, it is possible to easily obtain NiWO₄ having the Wolframite structure.

The layered structure as shown in FIG. 9 may also be formed by layering, for instance, TiO₂ having the hollandite structure as the second chemical compound on the NiWO₄ layer having the Wolframite structure. In this case, instead of separating out the Ni of a metal state on the electrode interface, Ni ions are accommodated in vacant sites of TiO₂ in addition to the advantage of the above-described elementary substance of the NiWO₄. With this, the resistance of the second chemical compound changes from a high resistance state to a low resistance state by the decrease of the valence of Ti. Therefore, also in the case of layering the first chemical compound and the second chemical compound, it is possible that the recording layer as a whole is caused to perform a phase change between the high resistance state and the low resistance state.

Experimental Example 1

Shown is an example in which ZrN was used as the buffer layer and NiWO₄ was used as the first chemical compound.

There was performed the film formation of ZrN on the n type (001) Si substrate by using a Zr target (diameter 100 mm). A natural oxide film was previously removed before the film formation. There was obtained ZrN oriented to the orientation of (100), as a result of RF magnetron sputtering, under the condition of RF power 60W, argon gas 97%, N₂ gas 3%, total gas pressure 0.3 Pa, and substrate temperature 500° C. The film thickness of ZrN was made to be 50 nm.

As the first chemical compound, a film of NiWO₄ was formed. The RF magnetron sputtering was performed in the atmosphere of Ar (argon) 95%, and O₂ (oxygen) 5%, while using the target in which the mixing ratio of the target was adjusted so as to be a stoichiometric composition at the time the film was formed. RF power was set to 100W, total gas pressure was set to 1.0 Pa, substrate temperature was set to 600° C., and film thickness of the first chemical compound NiWO₄ was set to 10 nm. At this time, the orientation of NiWO₄ was mainly in an “ac” plane orientation.

Lastly, a 2 nm SnO₂ film was formed as the protection film 13B to obtain a recording medium having the structure shown in FIG. 6.

Evaluation was performed by using an acicular probe pair whose leading edge diameter was 10 nm or less.

[Evaluation Method 1]

The voltage was applied in such a manner that one (probe 1) of the probes was caused to come into contact with the protection layer 13B to earth, and the other (probe 2) of the probes was caused to come into contact with the ZrN film. The write was performed by applying, for instance, the voltage pulse of 0.8V with 10 nsec width to the probe 2. The erase was performed by applying, for instance, the voltage pulse of 0.2V with 100 nsec width to the probe 2. Thus in the present experimental example, since the conductivity of ZrN was high, it was possible to cause ZrN to function as the lower electrode.

The read was executed between an interval of the write/erase. The read was performed in such a manner that the voltage pulse of 0.1V with 10 nsec width was applied to measure the resistance value of the recording layer (recording bit) 22.

As a result, the resistance of the high resistance state was in the 10⁶ Ω level, and the resistance of the low resistance state was in the 10⁴ Ω level.

[Evaluation Method 2]

Continuously, an evaluation is performed based on pulse erase. In this case, the write is performed by applying, for instance, the voltage pulse of 1.5V with 10 nsec width to the probe 2. The erase is performed by applying, for instance, the voltage pulse of −1.5V with 10 nsec width to the probe 2.

The read was executed between an interval of the write/erase. The read was performed in such a manner that the voltage pulse of 0.1V with 10 nsec width was applied to the probe 2 to measure the resistance value of the recording layer (recording bit) 22.

As a result, the resistance of the high resistance state was in the 10⁶ Ω level, and the resistance of the low resistance state was in the 10⁴ Ω level.

Experimental Example 2

By the same method as the experimental example 1, a NiWO₄ film having a film thickness of 10 nm with “ac” plane orientation was formed by using ZrN with (100) orientation as the buffer layer, on the n type (100) Si substrate.

Further, a TiO₂ film was obtained by performing the RF magnetron sputtering in the atmosphere of Ar (argon) 95%, and O₂ (oxygen) 5%, while using the Ti target (diameter 100 mm). RF power was set to 50 W, total gas pressure was set to 1.0 Pa, substrate temperature was set to 600° C., and film thickness of the second chemical compound TiO₂ was set to 3 nm. As a result of analysis of this TiO₂, the structure was the hollandite structure, and it was close to the “c” axis orientation.

Further, obtained was the recording medium having the structure shown in FIG. 9 while forming a SnO₂ film of 2 nm as the protection film 13B.

As a result of evaluating the recording medium in the same way as the evaluating method 1 of the experimental example 1, the resistance of the high resistance state was in the 10¹⁰ Ω level, and the resistance of the low resistance state was in the 10⁵ Ω level.

Similarly, as a result of evaluating the recording medium in the same way as the evaluating method 2 of the experimental example 1, the resistance of the high resistance state was in the 10¹⁰ Ω level, and the resistance of the low resistance state was in the 10⁵ Ω level.

Compartive Example

In the comparative example, the same sample as the first experimental example was used except that the first chemical compound was NiO. A film of NiO was formed on a VN film oriented to the (100) orientation by performing the RF magnetron sputtering in the atmosphere of Ar (argon) 95%, and O₂ (oxygen) 5%, while using NiO target (diameter 100 mm). RF power was set to 100 W, total gas pressure was set to 1.0 Pa, substrate temperature was set to 400° C., and film thickness of the first chemical compound NiO was set to 10 nm. At this time, the orientation of NiO was mainly in the (100) orientation.

In the present comparative example, since it was not possible to perform the write/erase in the case of applying the pulse of 1.5V with 10 nsec width as in the first experimental example, the write/erase was performed under the following conditions.

[Evaluation Method 1′]

The write is performed by applying the voltage pulse of 8V with 10 nsec width to the probe 2. The erase is performed by applying the voltage pulse of 2V with 1 μsec width to the probe 2.

The read was executed between an interval of the write/erase. The read was performed in such a manner that the voltage pulse of 0.1V with 10 nsec width was applied to the probe 2 to measure the resistance value of the recording layer (recording bit) 22.

As a result, the resistance of the high resistance state was in the 10⁷ Ω level, and the resistance of the low resistance state was in the 10⁴ Ω level.

[Evaluation Method 2′]

Continuously, evaluation is performed based on the pulse erase. In this case, the write is performed by applying, for instance, the voltage pulse of 5V with 10 nsec width to the probe 2. The erase is performed by applying, for instance, the voltage pulse of −5V with 10 nsec width to the probe 2.

The read was executed between an interval of the write/erase. The read was performed in such a manner that the voltage pulse of 0.1V with 10 nsec width was applied to the probe 2 to measure the resistance value of the recording layer (recording bit) 22.

As a result, the resistance of the high resistance state was in the 10⁷ Ω level, and the resistance of the low resistance state was in the 10⁴ Ω level.

Thus, in the case where NiO having the NaCl structure is used as the recording layer, since diffusion of cations is hard to be generated, there is a disadvantage that a large voltage is required for the write/erase.

D. Summary

According to such probe memory, it is possible to realize a higher recording density and lower power consumption than those of the present hard disk or flash memory.

(2) Semiconductor Memory

A. Structure

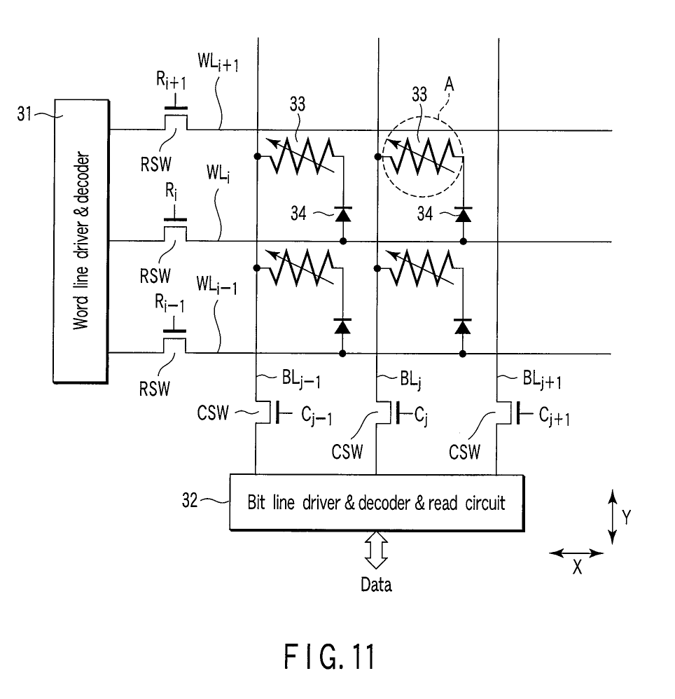

FIG. 11 shows a cross point type semiconductor memory according to an example.

Word lines WLi−1, WLi, and WLi+1 extend in X direction, and bit lines BLj−1, BLj, and BLj+1 extend in the Y direction.

Each one end of the word lines WLi−1, WLi, and WLi+1 is connected to a word line driver & decoder 31 via a MOS transistor RSW as a selection switch, and each one end of the bit lines BLj−1, BLj, and BLj+1 is connected to a bit line driver & decoder & read circuit 32 via a MOS transistor CSW as a selection switch.

Selection signals Ri−1, Ri, and Ri+1 for selecting one word line (row) are input to a gate of the MOS transistor RSW, and selection signals Ci−1, Ci, and Ci+1 for selecting one bit line (column) are input to a gate of the MOS transistor CSW.

A memory cell 33 is arranged at each intersection part of the word lines WLi−1, WLi, and WLi+1 and the bit lines BLj−1, BLj, and BLj+1. The memory cell 33 has a so called cross point cell array structure.

A diode 34 for preventing a sneak current at the time of recording/reproduction is added to the memory cell 33.

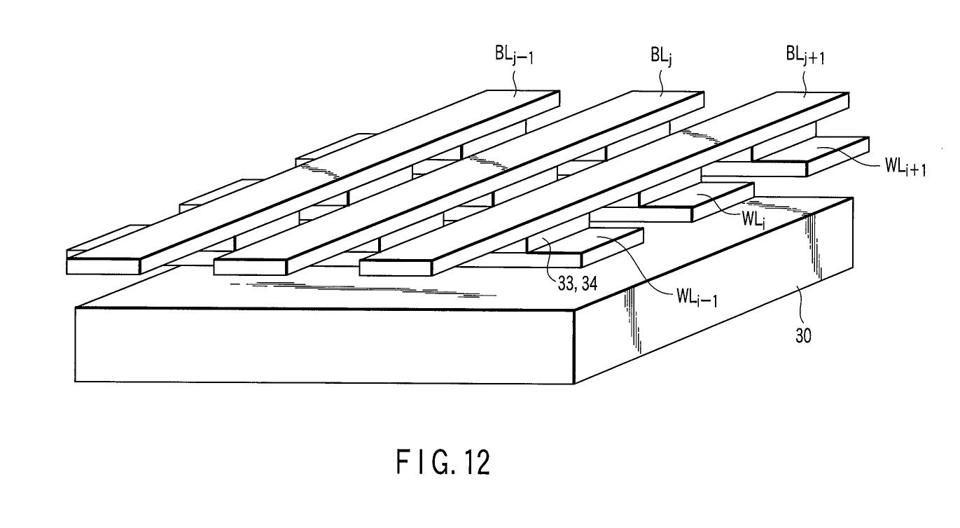

FIG. 12 shows a structure of a memory cell array part of the semiconductor memory of FIG. 11.

The word lines WLi−1, WLi, and WLi+1 and the bit lines BLj−1, BLj, and BLj+1 are arranged on a semiconductor chip 30, and the memory cells 33 and the diodes 34 are arranged in the intersection parts of these wirings.

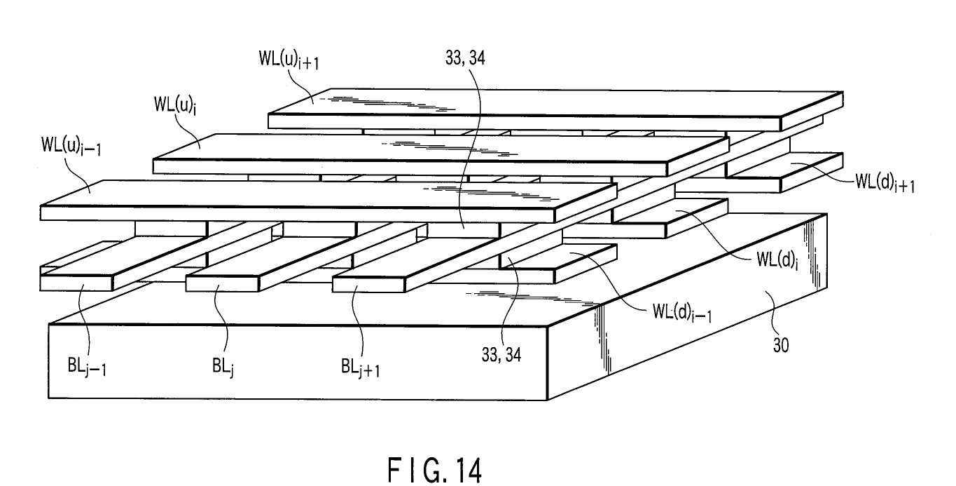

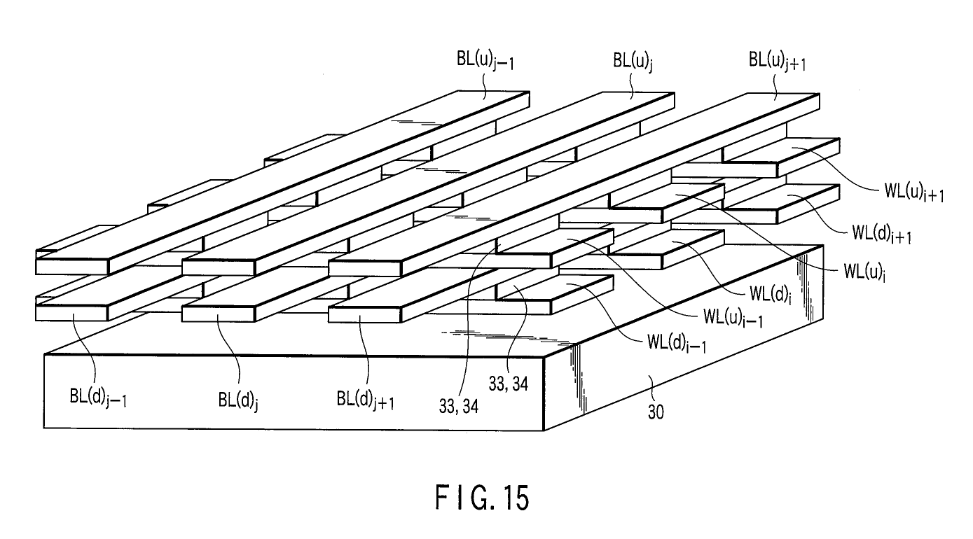

A feature of such a cross point type cell array structure lies in a point that, since it is not necessary to connect the MOS transistor individually to the memory cell 33, it is advantageous for high integration. For instance, as shown in FIGS. 14 and 15, it is possible to give the memory cell array a three-dimensional structure, by stacking the memory cells 33.

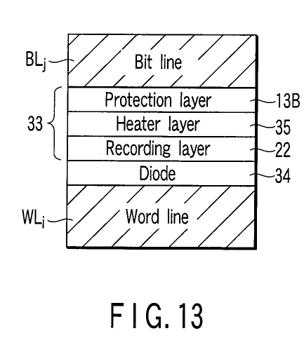

For instance, as shown in FIG. 13, the memory cell 33 is comprised a stack structure of a recording layer 22, a protection layer 13B and a heater layer 35. One bit data is stored in one memory cell 33. Further, the diode 34 is arranged between the word line WLi and the memory cell 33.

B. Recording/Reproducing Operation

A recording/reproducing operation will be explained using FIGS. 11 to 13.

Here, it is assumed that the recording/reproducing operation is executed while selecting the memory cell 33 surrounded by dotted line A.

First Example

The first example is a case in which the materials of FIG. 1 are used for the recording layer.

Since it is adequate for the recording (set operation) to apply the voltage to the selected memory cell 33 followed by generating potential gradients inside the memory cell 33 to cause current pulses to flow therein, for instance, there is prepared a state where the electric potential of the word line WLi is relatively lower than the electric potential of the bit line BLj. It is only necessary to provide a negative potential to the word line WLi when the bit line BLj has the fixed potential, for instance, ground potential.

At this time, in the selected memory cell 33 surrounded by the dotted line A, part of X ions moves to the word line (cathode) WLi side, and X ions inside the crystal relatively decrease to O ions. Further, X ions having moved to the word line WLi side separate out as metal while receiving the electrons from the word line WLi.

In the selected memory cell 33 surrounded by the dotted line A, O ions become excessive, and as a result, the valence of X ions inside the crystal is caused to increase. That is, the selected memory cell 33 surrounded by the dotted line A comes to have larger electrical conductivity due to implantation of carriers caused by phase change, thereby completing the recording (set operation).

Similarly, at the time of recording, with respect to non selected word lines WLi−1, WLi+1, and non selected bit lines BLj−1, BLj+1, it is preferable that all are biased into the same electric potential.

Further, at the time of standby before recording, it is preferable for all of the word lines WLi−1, WLi, and WLi+1, and the bit lines BLj−1, BLj, and BLj+1, to become pre-charged.

Further, the current pulse for recording may be generated by preparing the state where the electric potential of the word line WLi is relatively higher than the electric potential of the bit line BLj.

The reproduction is performed by detecting a resistance value of the memory cell 33 while causing the current pulse to flow through the selected memory cell 33 surrounded by the dotted line A. However, it is necessary for the current pulse to be a minute value to the degree that the material constituting the memory cell 33 does not cause resistance changes.

For instance, the read current (current pulse) generated by a read circuit is caused to flow through the selected memory cell 33 surrounded by the dotted line A from the bit line BLj, and the resistance value of the memory cell 33 is measured by the read circuit. If adopting the new materials described above, the difference in the resistance value between the set/reset states can be secured at 10³ or more.

The erase (reset) operation is performed by facilitating the oxidation-reduction reaction in the memory cell 33 while performing joule heating of the selected memory cell 33 surrounded by the dotted line A by a large-current pulse.

Second Example

The second example is a case in which the materials of FIG. 2 are used for the recording layer.

Since it is adequate for the recording (set operation) to apply the voltage to the selected memory cell 33 followed by generating potential gradients inside the memory cell 33 to cause current pulses to flow therein, for instance, there is prepared a state where the electric potential of the word line WLi is relatively lower than the electric potential of the bit line BLj. It is only necessary to provide a negative potential to the word line WLi when the bit line BLj has the fixed potential, for instance, ground potential.

At this time, in the selected memory cell 33 surrounded by the dotted line A, part of X ions inside the first chemical compound moves to the vacant site of the second chemical compound. For this reason, the valence of X ions inside the first chemical compound increases, and the valence of M ions inside the second chemical compound decreases. As a result, the conductive carriers are generated inside the crystal of the first and second chemical compounds, and both come to have electrical conductivity.

Herewith, the set operation (recording) is completed.

Likewise, at the time of recording, with respect to non selected word lines WLi−1, WLi+1, and non selected bit lines BLj−1, BLj+1, it is preferable that all are biased with the same electric potential.

Further, at the time of standby before recording, it is preferable for all of the word lines WLi−1, WLi, and WLi+1, and the bit lines BLj−1, BLj, and BLj+1, to become pre-charged.

Further, the current pulse may be generated by preparing the state where the electric potential of the word line WLi is relatively higher than the electric potential of the bit line BLj.

The reproducing operation is performed by detecting the resistance value of the memory cell 33 while causing the current pulse to flow through the selected memory cell 33 surrounded by the dotted line A. However, it is necessary for the current pulse to be a minute value to the degree that the material constituting the memory cell 33 does not cause resistance changes.

For instance, the read current (current pulse) generated by the read circuit is caused to flow through the selected memory cell 33 surrounded by the dotted line A from the bit line BLj, and the resistance value of the memory cell 33 is measured by the read circuit. If adopting the new materials described above, the difference in the resistance value between the set/reset states can be secured at 10³ or more.

The reset (erase) operation may be performed by facilitating the action in which X ion element returns to the first chemical compound from the vacant site inside the second chemical compound while utilizing the joule heat and its residual heat generated by causing the large-current pulse to flow through the selected memory cell 33 surrounded by the dotted line A.

Here, when the inside of the recording layer 22 formed at the intersection part of the word line WLi and the bit line BLj exists in a polycrystalline state or a monocrystalline state, it is preferable since diffusion of the ions inside the crystal easily occurs. However, also in this case, when the size of the crystal grain differs largely at respective memory cells, there is a possibility that the characteristic of the recording layer in respective memory cells varies. Therefore, it is preferable that in the respective memory cell, the size of crystal grain is approximately uniform, and that the distribution thereof follows the distribution having a single peak. In this case, it is assumed that the size of the crystal grain severed at an interface of each intersection part is not taken into consideration at the time distribution is obtained. In order to utilize movement of the diffusion ions inside the crystal structure, it is preferable that the size of the crystal grains in the recording film cross sectional direction is 3 nm or more, more preferably 5 nm or more. Assuming that the size of the intersection part becomes smaller than about 20 nm, it is preferable that the number of the crystal grains included in the respective intersection parts is 10 or less. Further, it is more preferable that the number of the crystal grains is 4 or less.

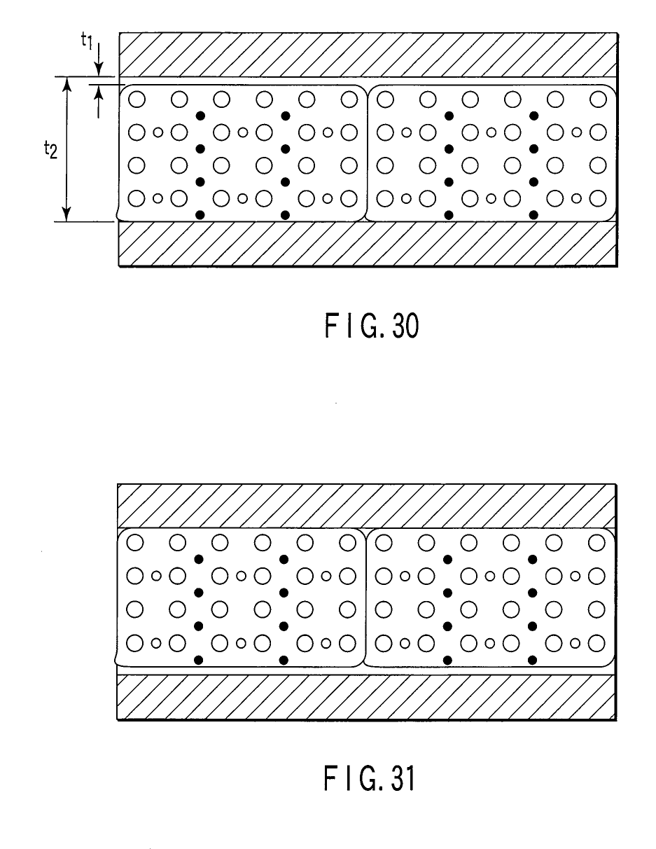

Next, there is considered the size of the crystal grain in the film thickness direction. In order that the resistance change is generated efficiently by the diffusion inside the crystal structure, it is preferable for the size in the film thickness direction of the crystal grain to be of the same degree or more as the film thickness. However, when layering no second chemical compound, the recording layer may have a minimal amorphous part at an upper part or lower part of the crystal part of the first chemical compound. This will be explained using FIGS. 30 and 31. As described using FIG. 1, A ions separate out as A metal inside the recording layer, after being diffused via the diffusion path. At this time, when A ions separate out at an interface part of the first chemical compound being in the amorphous state while diffusing to an end part of crystal grain of the first chemical compound, it is preferable because there is the vacancy to be occupied by A ions. However, when the film thickness t1 of the layer being in the amorphous state becomes excessively large, the recording layer as a whole does not cause the resistance change efficiently. Generally, the resistance of the amorphous part takes a value between a resistance of the case where the first chemical compound is in an insulating state and a resistance of the case where the first chemical compound is in a conductive state. Since the resistance change of the amorphous layer due to movement of A ions is not large, in order that the resistance change of the recording film is made more than an order of magnitude, it is preferable for the film thickness t1 of the amorphous layer to be 1/10 or less of t2.

The amorphous layer may exist on either the upper part or lower part of the first chemical compound. However, in order to orient the first chemical compound in a required direction, generally, orientation control is performed by using a lower layer which agrees with the first chemical compound in lattice constant, and therefore, it is preferable for the amorphous part to exist on the upper part of the first chemical compound.

Further, the amorphous layer may be generated at the time a next layer contacting the recording layer is formed. In such a case, the composition of the amorphous layer, which is different from the composition inside the first chemical compound, includes part of the materials of the next layer contacting the recording layer, and the amorphous layer has an effect of enhancing the adhesion property between the recording film material and the next layer. In this case, film thickness t1 of the amorphous layer becomes 10 nm or less. It is more preferable for t1 to be 3 nm or less.

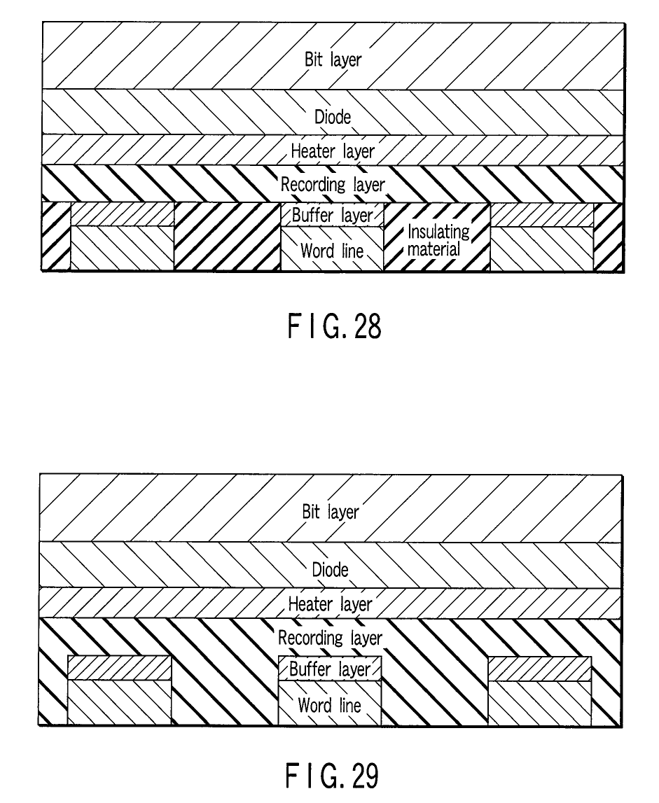

Continuously, there is considered the interface of the respective interconnection parts. When the recording layer is subjected to a process in which the recording layer is fabricated in the same shape as the word line after forming the recording layer uniformly, there is a possibility that the characteristic of the fabricated face of the recording layer is different from that inside the crystal. As a method for avoiding this influence, there is a method in which a uniform recording layer is used without processing, by using the recording layer to become an insulator at the time of film formation. In this case, as shown in FIG. 28, in the case where a space between the word lines is embedded with materials having an insulating property, it is only necessary that the recording layer is formed on the word lines and the insulator. Alternatively, in the case where the recording film material functions as an insulator of the space between the word lines, as shown in FIG. 29, the recording layer may be formed on the word line and on the substrate. Thus, it is possible to form arbitrary films before forming the recording layer. In FIGS. 28 and 29, there is shown an example in which a buffer layer is formed to suppress diffusion of the recording layer material before the recording layer is formed. In the case where the buffer layer is made of the insulator, the buffer layer may be provided all over the lower part of the recording layer material in advance. In FIGS. 28 and 29, the case where the recording film is uniform is shown. However, in the case where the recording layer is processed only in the direction of the bit line or the word line, or where the recording layer is processed to be larger than the respective intersection points, similarly, it is possible to alleviate the influence of a processed face.

C. Summary According to such semiconductor memory, a higher recording density and lower power consumption than those of the existing hard disk or flash memory can be realized.

### 4. Application of a Flash Memory

(1) Structure

The example of the present invention can also be applied to the flash memory.

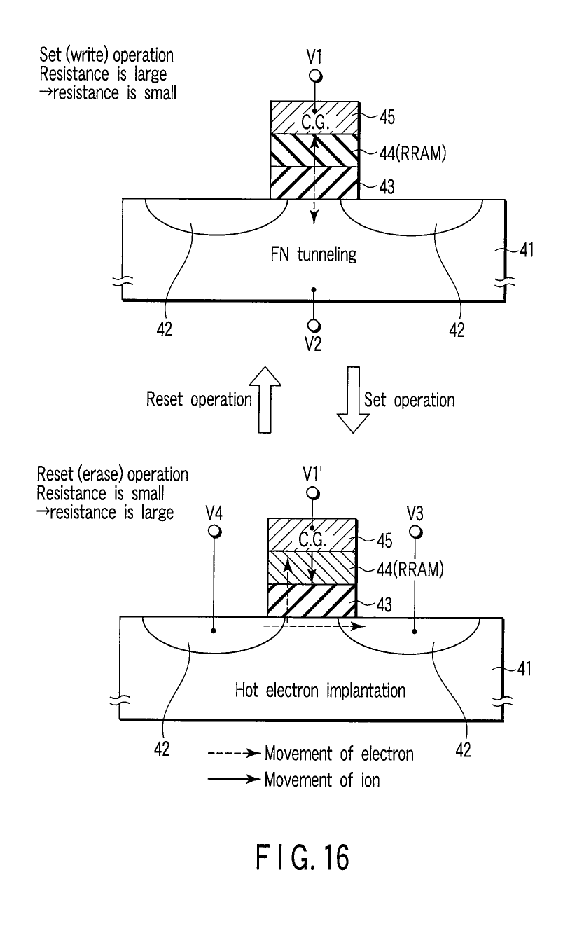

FIG. 16 shows a memory cell of the flash memory.

The memory cell of the flash memory is comprised a MIS (metal-insulator-semiconductor) transistor.

A diffusion layer 42 is formed in a surface region of a semiconductor substrate 41. A gate insulating layer 43 is formed on a channel region between the diffusion layers 42. A recording layer (ReRAM: Resistive RAM) 44 according to an example of the present invention is formed on the gate insulating layer 43. A control gate electrode 45 is formed on the recording layer 44.

The semiconductor substrate 41 may be a well region, and the semiconductor substrate 41 and the diffusion layer 42 have reverse conductivity types mutually. The control gate electrode 45 becomes the word line, and is comprised a conductive polysilicon.

The recording layer 44 is comprised the materials shown in FIG. 1, 2 or 3.

(2) Fundamental Operation

Explanation will now be made about the fundamental operation using FIG. 16.

A set (write) operation is executed by providing an electric potential V1 to the control gate electrode 45, and providing an electric potential V2 to the semiconductor substrate 41.

The difference between the electric potentials V1, V2 needs to be sufficiently large for the recording layer 44 to cause a phase change or a resistance change, but its direction is not limited particularly.

That is, either V1>V2 or V1<V2 may be applied.

For instance, in an initial state (reset state), assuming that the recording layer 44 is an insulator (resistance is large), the gate insulating layer 43 becomes quite thick. As a result, a threshold of the memory cell (MIS transistor) becomes high.

When the recording layer 44 is caused to change into a conductor (resistance is small) while providing the electric potentials V1, V2 from this state, the gate insulating layer 43 becomes quite thin. As a result, a threshold of the memory cell (MIS transistor) becomes low.

Note that, although the electric potential V2 is supplied to the semiconductor substrate 41, the electric potential V2 may be instead transferred to the channel region of the memory cell from the diffusion layer 42.

The reset (erase) operation is executed in such a manner that the electric potential V1′ is supplied to the control gate electrode 45, the electric potential V3 is supplied to one of the diffusion layers 42, and the electric potential V4 (<V3) is supplied to the other one of the diffusion layers 42.

The electric potential V1′ is set to a value exceeding the threshold of the memory cell being in the set state.

At this time, the memory cell becomes ON, the electrons flow toward one direction from the other direction of the diffusion layer 42, and hot electrons are generated. Since the hot electrons are implanted into the recording layer 44 via the gate insulating layer 43, the temperature of the recording layer 44 increases.

Herewith, since the recording layer 44 changes to the insulator (resistance is large) from the conductor (resistance is small), the gate insulating layer 43 becomes quite thick. Accordingly, the threshold of the memory cell (MIS transistor) becomes high.

In this manner, by a similar principle to the flash memory, the threshold of the memory cell can be changed, and therefore, it is possible to put the information recording/reproducing device according to the example of the present invention into practical use, while utilizing the technique of the flash memory.

(3) NAND Type Flash Memory

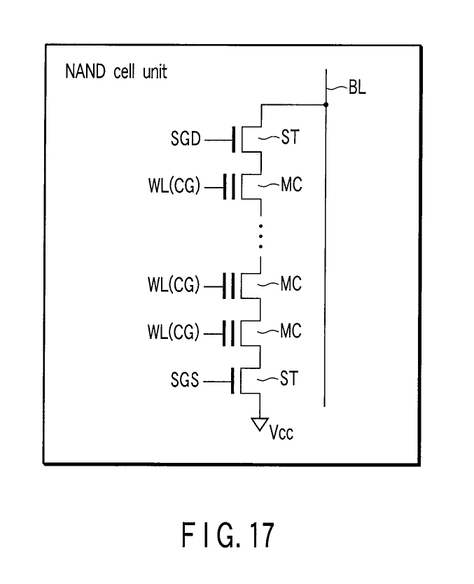

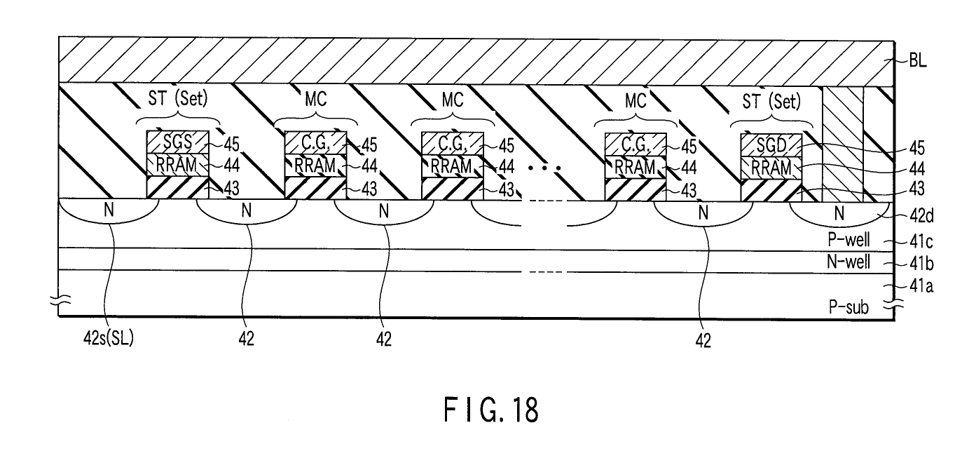

FIG. 17 shows a circuit diagram of a NAND cell unit. FIG. 18 shows a structure of the NAND cell unit according to the example.

An N type well region 41b and a P type well region 41c are formed inside a P type semiconductor substrate 41a. A NAND cell unit according to the example of the present invention is formed inside the P type well region 41c.

The NAND cell unit is comprised of a NAND string comprised a plurality of memory cells MC connected in series, and a total of two select gate transistors ST connected one by one to the both ends of the NAND string.

The memory cell MC and the select gate transistor ST have the same structure. Specifically, these are comprised an N type diffusion layer 42, a gate insulating layer 43 on the channel region between the N type diffusion layers 42, a recording layer (ReRAM) 44 on the gate insulating layer 43, and a control gate electrode 45 on the recording layer 44.

States (insulator/conductor) of the recording layer 44 of the memory cell MC can be changed by the above-described fundamental operation. On the other hand, the recording layer 44 of the select gate transistor ST is fixed to the set state, that is, the conductor (resistance is small).

One of the select gate transistors ST is connected to a source line SL, and the other one is connected to a bit line BL.

Before set (write) operation, it is assumed that all memory cells inside the NAND cell unit are in the reset state (resistance is large).

The set (write) operations are performed one by one in order toward the memory cell at the bit line BL side from the memory cell MC at the source line SL side.

V1 (plus potential) is supplied as the write potential to the selected word line (control gate electrode) WL, and Vₚₐₛₛ is supplied as a transfer potential (electric potential by which memory cell MC becomes ON) to the non selected word line WL.

Program data is transferred to the channel region of the selected memory cell MC from the bit line BL, in the state that the select gate transistor ST at the source line SL side is made OFF, and the select gate transistor ST at the bit line BL side is made ON.

For instance, when the program data is “1”, a write inhibit potential (for instance, electric potential being the same degree as V1) is transferred to the channel region of the selected memory cell MC, so that the resistance value of the recording layer 44 of the selected memory cell MC does not change into the low state from the high state.

Further, when the program data is “0”, V2 (<V1) is transferred to the channel region of the selected memory cell MC, and the resistance value of the recording layer 44 of the selected memory cell MC is changed into the low state from the high state.

In the reset (erase) operation, for instance, V1′ is supplied to all the word lines (control gate electrode) WL to make all the memory cells MC inside the NAND cell unit ON. Further, the two select gate transistors ST are turned ON, V3 is supplied to the bit line BL, and V4 (<V3) is supplied to the source line SL.

At this time, since the hot electrons are implanted to the recording layer 44 of all the memory cells MC inside the NAND cell unit, the reset operation is collectively executed to all memory cells MC inside the NAND cell unit.

The read operation is performed in such a manner that a read potential (plus potential) is supplied to the selected word line (control gate electrode) WL, and electric potentials by which the memory cell MC becomes inevitably ON regardless of the data “0”, “1” are supplied to the non selected word line (control gate electrode) WL.

Further, the two select gate transistors ST are turned ON, and the read current is supplied to the NAND string.

Since the selected memory cell MC, when applied with the read potential, becomes ON or OFF in accordance with data value stored therein, it is possible to read the data by, for instance, detecting changes of the read current.

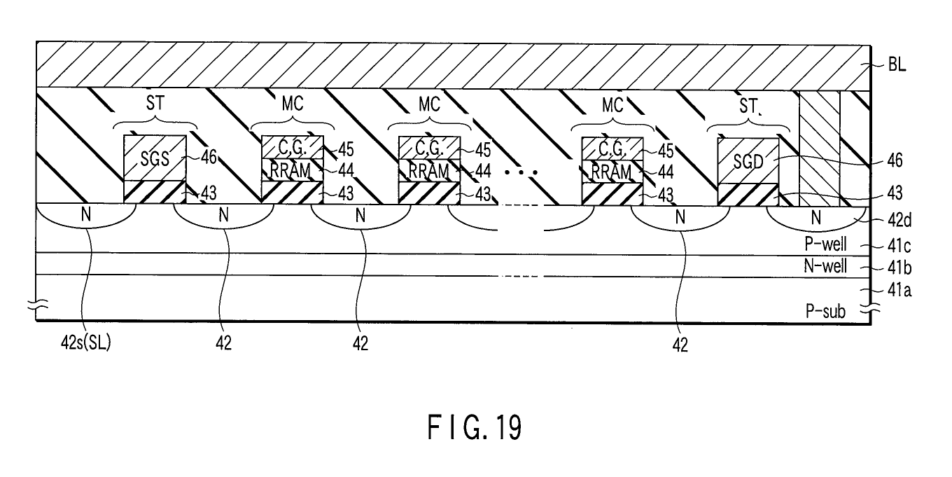

In the structure of FIG. 18, the select gate transistor ST has the same structure as the memory cell MC. However, for instance, as shown in FIG. 19, the select gate transistor ST may be a normal MIS transistor without forming the recording layer.

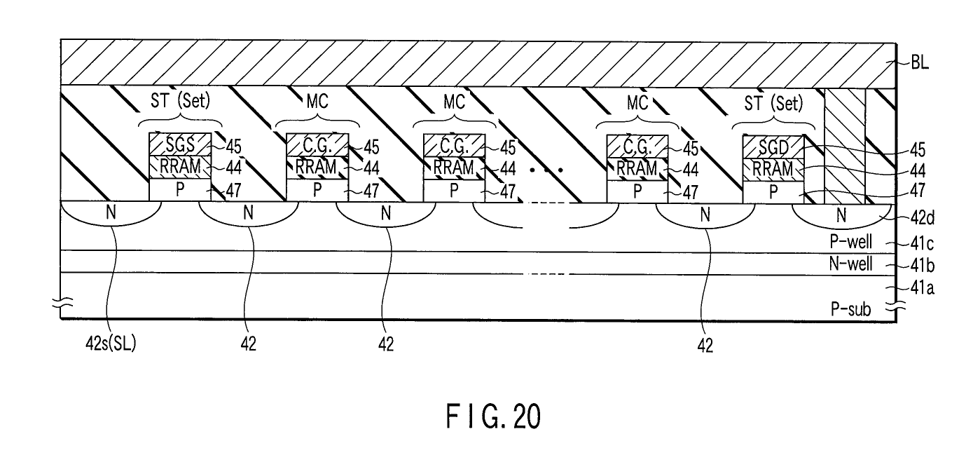

FIG. 20 shows a modified example of the NAND type flash memory.

The modified example is characterized in that the gate insulating layer of a plurality of memory cells MC constituting the NAND string is replaced with a P type semiconductor layer 47.

When high integration is advanced and the memory cell MC is miniaturized, in a state where the voltage is not supplied, the P type semiconductor layer 47 is filled with a depletion layer.

At the time of set (write), a plus write potential (for instance, 3.5V) is supplied to the control gate electrode 45 of the selected memory cell MC, and a plus transfer potential (for instance, 1V) is supplied to the control gate electrode 45 of the non selected memory cell MC.

At this time, a surface of the P type well region 41c of a plurality of memory cells MC inside the NAND string inverts from P type to N type, so that a channel is formed.

Consequently, as described above, when the select gate transistor ST at the bit line BL side is turned ON, and the program data “0” is transferred to the channel region of the selected memory cell MC from the bit line BL, it is possible to perform the set operation.

The reset (erase) can be collectively performed to all the memory cells MC constituting the NAND string, when, for instance, minus erase potential (for instance, −3.5V) is supplied to all the control gate electrodes 45, and the ground potential (0V) is supplied to the P type well region 41c and the P type semiconductor layer 47.

At the time of the read, the plus read potential (for instance, 0.5V) is supplied to the control gate electrode 45 of the selected memory cell MC, and the transfer potential (for instance, 1V) by which the memory cell MC becomes inevitably ON regardless of the data “0”, “1” is supplied to the control gate electrode 45 of the non selected memory cell MC.

It is assumed that the threshold voltage Vth “1” of the memory cell MC of “1” state should fall in the range of 0V<Vth “1”<0.5V, and the threshold voltage Vth “0” of the memory cell MC of “0” state should fall in the range of 0.5V<Vth “0”<1V.

Further, the read current is supplied to the NAND string while making the two select gate transistors ST ON.

When such state is realized, since current quantity flowing through the NAND string is changed in accordance with the data value stored in the selected memory cell MC, it is possible to read the data by detecting this change.

Meanwhile, in this modified example, it is desirable that the hole dope amount of the P type semiconductor layer 47 is more than that of the P type well region 41c, and the Fermi level of the P type semiconductor layer 47 is deeper than that of the P type well region 41c by about 0.5V.

This is because when a plus potential is supplied to the control gate electrode 45, an inversion from P type to N type commences from a surface part of the P type well region 41c between the N type diffusion layers 42, so that the channel is to be formed.

Accordingly, for instance, at the time of the write, the channel of the non selected memory cell MC is formed only at an interface between the P type well region 41c and the P type semiconductor layer 47, and at the time of the read, the channel of a plurality of memory cells MC inside the NAND string is formed only at an interface between the P type well region 41c and the P type semiconductor layer 47.

That is, even though the recording layer 44 of the memory cell MC is in the conductor (set state), the diffusion layer 42 and the control gate electrode 45 do not short-circuit.

(4) NOR Type Flash Memory

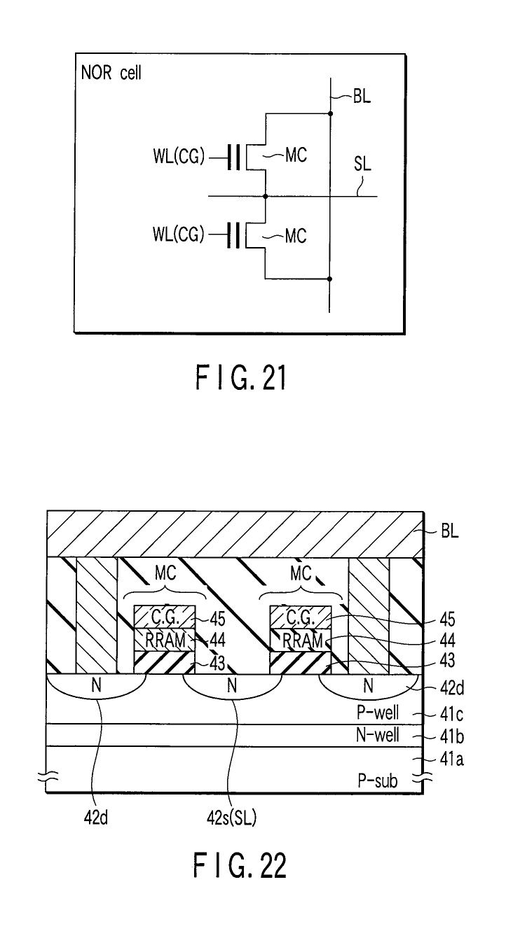

FIG. 21 shows a circuit diagram of a NOR cell unit. FIG. 22 shows a structure of the NOR cell unit according to an example of the present invention.

An N type well region 41b and a P type well region 41c are formed inside a P type semiconductor substrate 41a. The NOR cell according to the example of the present invention is formed inside the P type well region 41c.

The NOR cell is comprised one memory cell (MIS transistor) MC connected between the bit line BL and the source line SL.

The memory cell MC is comprised an N type diffusion layer 42, a gate insulating layer 43 on the channel region between the N type diffusion layers 42, a recording layer (ReRAM) 44 on the gate insulating layer 43, and a control gate electrode 45 on the recording layer 44.

The state (insulator/conductor) of the recording layer 44 of the memory cell MC can be changed by the above-described fundamental operation.

(5) 2-Transistor Type Flash Memory

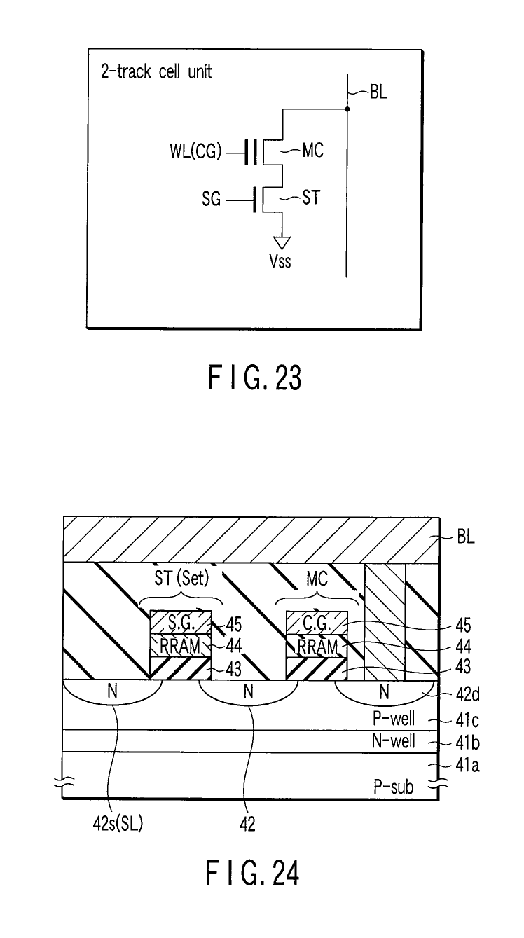

FIG. 23 shows a circuit diagram of a 2-transistor cell unit. FIG. 24 shows a structure of the 2-transistor cell unit according to the example.

The 2-transistor cell unit has been developed recently as a new cell structure having characteristic of the NAND cell unit in conjunction with characteristic of the NOR cell.

An N type well region 41b and a P type well region 41c are formed inside a P type semiconductor substrate 41a. The 2-transistor cell unit according to the example of the present invention is formed inside the P type well region 41c.

The 2-transistor cell unit is comprised one memory cell MC and one select gate transistor ST connected in series.

The memory cell MC and the select gate transistor ST have the same structure. Specifically, these are comprised an N type diffusion layer 42, a gate insulating layer 43 on the channel region between the N type diffusion layers 42, a recording layer (ReRAM) 44 on the gate insulating layer 43, and a control gate electrode 45 on the recording layer 44.

The state (insulator/conductor) of the recording layer 44 of the memory cell MC can be changed by the above-described fundamental operation. On the other hand, the recording layer 44 of the select gate transistor ST is fixed to the set state, that is, the conductor (resistance is small).

The select gate transistor ST is connected to the source line SL, and the memory cell MC is connected to the bit line BL.

States (insulator/conductor) of the recording layer 44 of the memory cell MC can be changed by the above-described fundamental operation.

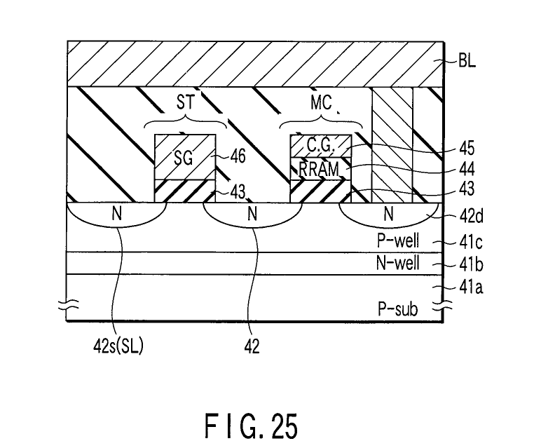

In the structure of FIG. 24, the select gate transistor ST has the same structure as the memory cell MC. However, for instance, as shown in FIG. 25, the select gate transistor ST may be a normal MIS transistor without forming the recording layer.

### 5. Others

According to the example of the present invention, since information recording (write) is only performed in a site (recording unit) to which the electric field is applied, information can be recorded in a very minute region with very small power consumption.

Further, the erase is performed by applying heat. In this case, if the materials proposed by the example of the present invention are used, structural change of the oxide is hardly generated, and therefore, the erase becomes possible with small power consumption. Alternatively, the erase can be performed by applying an electric field of inverse direction to the one at the time of the recording. In such a case, since the energy loss of diffusion of heat is small, the erase becomes possible with smaller power consumption.

Further, by constituting the host structure using cations with a large valence, the host structure is hardly changed by diffusion of the cations, and is thermally stable.

Thus, according to the example of the present invention, despite a very simple mechanism, it is possible to perform the information recording with the recording density which has been impossible with the conventional technique. Therefore, the example of the invention has a substantial industrial merit as a next-generation technology overcoming the limit of the recording density of the existing nonvolatile memory.

The example of the present invention is not restricted to the above-described embodiment, and it can be embodied while transforming respective constituent elements in the scope without departing from the spirit of the invention. Further, various inventions can be comprised by appropriate combination of a plurality of constituent elements disclosed in the above embodiments. For instance, some constituent elements may be deleted from all the constituent elements disclosed in the above-described embodiments, or the constituent elements in different embodiments may be appropriately combined.

What is claimed is:

1. An information recording/reproducing device comprising:
a recording layer; and
means for recording information by generating a phase change in the recording layer while applying a voltage to the recording layer,
wherein the recording layer includes a first chemical compound having at least one of a Wolframite structure and a Scheelite structure.

2. The device according to claim 1, wherein the first chemical compound is comprised a material represented by at least a chemical formula 1: XₐY_{b}O₄ (0.5≦a≦1.1, 0.7≦b≦1.1), and
the X includes at least one transition element having a “d” orbit where electrons are incompletely filled.

3. The device according to claim 2, wherein the Y includes at least one element selected from the group of Mo and W.

4. The device according to claim 2, wherein the Y includes at least W.

5. The device according to claim 2, wherein the X includes at least one element selected from the group of Ti, V, Mn, Fe, Co, and Ni.

6. The device according to claim 2, wherein the X includes at least one element selected from the group of Fe, Co, and Ni.

7. The device according to claim 2, wherein the X includes at least one element selected from either Fe or Ni.

8. The device according to claim 2, wherein the first chemical compound has the Wolframite structure, and an “a” axis of the recording layer is oriented horizontally or oriented in a range of 45 degrees from level.

9. The device according to claim 2, further comprising a second chemical compound coming into contact with the first chemical compound and having an vacant site capable of accommodating cations.

10. The device according to claim 9, wherein the second chemical compound is one of:
□_{X}MZ₂ chemical formula 2:
wherein □ is an vacant site in which the X ion is accommodated, M each includes at least one element selected from Ti, V, Cr, Mn, Fe, Co, Ni, Nb, Ta, Mo, W, Re, Ru, and Rh, Z each includes at least one element selected from O, S, Se, N, Cl, Br, and I, and x falls in a range of 0.3≦x≦1;
□_{X}MZ₃ chemical formula 3:
wherein □ is the vacant site in which the X ion is accommodated, M each includes at least one element selected from Ti, V, Cr, Mn, Fe, Co, Ni, Nb, Ta, Mo, W, Re, Ru, and Rh, Z each includes at least one element selected from O, S, Se, N, Cl, Br, and I, and x falls in a range of 1≦x≦2;
□_{X}MZ₄ chemical formula 4:
wherein □ is the vacant site in which the X ion is accommodated, M each includes at least one element selected from Ti, V, Cr, Mn, Fe, Co, Ni, Nb, Ta, Mo, W, Re, Ru, and Rh, Z each includes at least one element selected from O, S, Se, N, Cl, Br, and I, and x falls in a range of 1≦x≦2;
□_{X}MPO_{Z} chemical formula 5:
wherein □ is the vacant site in which the X ion is accommodated, M each includes at least one element selected from Ti, V, Cr, Mn, Fe, Co, Ni, Nb, Ta, Mo, W, Re, Ru, and Rh, P is a phosphorus element, O is an oxygen element, x falls in a range of 0.3≦x≦3, and z falls in a range of 4≦z≦6; and
□_{X}M₂Z₅ chemical formula 6:
wherein □ is the vacant site in which the X ion is accommodated, M each includes at least one element selected from V, Cr, Mn, Fe, Co, Ni, Nb, Ta, Mo, W, Re, Ru, and Rh, Z each includes at least one element selected from O, S, Se, N, Cl, Br, and I, and x falls in a range of 1≦x≦2.

11. The device according to claim 9, wherein the second chemical compound has one of a hollandite structure, ramsdellite structure, anatase structure, brookite structure, pyrolusite structure, ReO₃ structure, MoO_{1.5}PO₄ structure, TiO_{0.5}PO₄ structure, FePO₄ structure, βMnO₂ structure, γMnO₂ structure, and λMnO₂ structure.

12. The device according to claim 9, wherein the second chemical compound has one of the ramsdellite structure and the hollandite structure.

13. The device according to claim 9, wherein a Fermi level of electrons of the first chemical compound is lower than a Fermi level of electrons of the second chemical compound.

14. The device according to claim 1, wherein the means includes a probe to apply the voltage locally to a recording unit of the recording layer.

15. The device according to claim 1, wherein the means includes a word line and a bit line sandwiching the recording layer.

16. The device according to claim 1, wherein the means includes a MIS transistor, and the recording layer is arranged between a gate electrode and a gate insulating layer of the MIS transistor.

17. The device according to claim 1, wherein the means includes two second conductive type diffusion layers inside a first conductive type semiconductor substrate, a first conductive type semiconductor layer on the first conductive type semiconductor substrate between the two second conductive type diffusion layers, and a gate electrode which controls conduction/non-conduction between the two second conductive type diffusion layers, and
the recording layer is arranged between the gate electrode and the first conductive type semiconductor layer.
